(19) United States
(12) Patent Application Publication
(10) Pub. No.: US 2013/0199604 A1
(43) Pub. Date: Aug. 8, 2013

(54) SOLAR CELLS AND METHODS OF FABRICATION THEREOF

(71) Applicant: Silicon Solar Solutions, Fayetteville, AR (US)

(72) Inventors: Seth Daniel Shumate, Fayetteville, AR (US); Douglas Arthur Hutchings, Elkins, AR (US); Hafeezuddin Mohammed, Fayetteville, AR (US)

(73) Assignee: Silicon Solar Solutions, Fayetteville, AR (US)

(21) Appl. No.: 13/754,863

(22) Filed: Jan. 30, 2013

Related U.S. Application Data
(60) Provisional application No. 61/595,504, filed on Feb. 6, 2012.

(51) Int. Cl. H01L 31/0352; H01L 31/18; H01L 31/0232

(52) U.S. Cl. CPC H01L 31/035272; H01L 31/0232; H01L 31/18
USPC 136/255; 438/72; 438/87

(57) ABSTRACT

A solar cell comprises a region formed on a substrate. The region has a dopant. The region can be one of a selective emitter and a back surface field of the solar cell. A grid line is deposited over a first portion of the region. A dopant profile is generated that has a concentration of electrically active dopants at a surface portion on the first portion of the region smaller than the concentration of electrically active dopants at a distance away from the surface portion. In an embodiment, an electrical activity of a portion of the dopant is deactivated in a second portion of the region outside the grid line. The grid line is used as a mask for deactivating the dopant.

This application claims the benefit of prior U.S. Provisional Patent Application No. 61/595,504, entitled “SELF-ALIGNED HYDROGENATED SELECTIVE EMITTER FOR N-TYPE SOLAR CELLS”, filed Feb. 6, 2012, which is hereby incorporated by reference in its entirety.

### TECHNICAL FIELD

Embodiments of the present invention are in the field of renewable energy and, in particular, to solar cells and methods of fabrication thereof.

### BACKGROUND

Generally, solar cells are known as devices that convert solar radiation into electrical energy. Typically, solar cells are fabricated on a semiconductor substrate using semiconductor processing techniques to form a p-n junction near a surface of the substrate. Solar radiation incident upon the surface of the substrate creates electron and hole pairs in the bulk of the substrate. The electron and hole pairs migrate to p-doped and n-doped regions in the substrate, thereby generating a voltage differential between the doped regions. The doped regions are coupled to metal contacts on the solar cell to direct an electrical current from the cell to an external circuit coupled thereto. Radiation conversion efficiency is an important characteristic of a solar cell as it is directly related to the solar cell's capability to generate electrical power.

FIG. 1 is an illustration of a cross-sectional view of a typical homogeneous emitter solar cell structure 100. As shown in FIG. 1, a highly doped p⁺-type silicon emitter 102 is formed on n-type silicon substrate 101. Metal grid lines, such as a metal grid line 104 are formed on the emitter 102. An antireflective coating (“AR”) 103 is deposited on the portion of the emitter 102 between the grid lines. The conventional homogeneous emitter, such as emitter 102, has uniform doping profile underneath and between grid contacts. The active dopant concentration at the surface of the homogeneously doped emitter is generally at least 10²⁰ cm⁻³ to form an ohmic contact with the grid line and to obtain a high fill factor which is typically defined as a ratio of the actual maximum obtainable power to the product of the open circuit voltage and short circuit current.

High concentration of the active dopants at the surface of the emitter creates high surface recombination velocities. High surface recombination velocity limits open-circuit voltage (Voc) and short-circuit current (Jsc) directly limiting the conversion efficiency of the solar cell.

A selective emitter is used to avoid the limitations caused by the homogeneous emitter. Selective emitters have high dopant concentration beneath grid lines and low dopant concentration between the grid lines. The conventional selective emitter techniques require two or more processing steps to achieve this.

One selective emitter technique starts with the lightly doped Si emitter. Then highly doped silicon paste is selectively applied through a mask to the regions of the lightly doped Si emitter where the grid lines are going to be placed. Then, the grid lines are formed on the highly doped silicon paste regions.

Another selective emitter technique starts with highly doped Si emitter. A hard mask is deposited on the highly doped emitter. The portions of the highly doped Si emitter are etched back through a hard mask to reduce doping in those portions of the Si emitter that are between the grid lines. The grid lines are then deposited on the un-etched highly doped regions of the emitter.

Another selective emitter technique uses at least two separate steps of ion implantation to produce high doping of the emitter underneath the grid lines and low doping of the emitter between the grid lines.

All conventional selective emitter techniques require complicated alignment processing and have generally low yield. The surface doping achieved with these techniques provides high sheet resistances that are more than 100 Ω/sq. Such high sheet resistances cause a lot of power loss, so that conventional selective emitters require up to 50% more grid lines than the homogeneous emitter. Because the grid metallization typically contains silver, this is a very expensive requirement.

### BRIEF DESCRIPTION OF THE DRAWINGS

FIG. 1 is an illustration of a cross-sectional view of a typical homogeneous emitter solar cell structure 100.

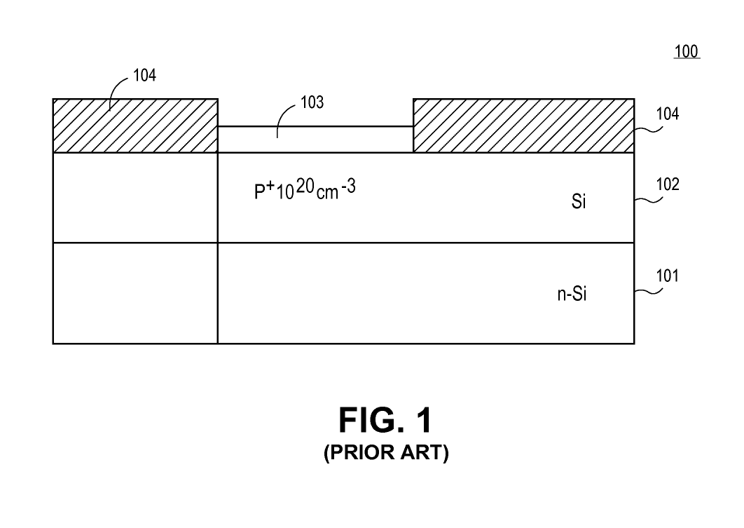

FIG. 2 is an illustration of a solar cell panel top view according to one embodiment of the invention.

FIG. 3 is an illustration of a cross-sectional view of a portion of a solar cell panel according to one embodiment of the invention.

FIG. 4 is an illustration of a view of a solar cell having grid lines according to one embodiment of the invention.

FIG. 5 is an illustration of a portion of a solar cell according to one embodiment of the invention.

FIG. 6A is an illustration of a cross-sectional view of a portion of a solar cell according to one embodiment of the invention.

FIG. 6B is a view similar to FIG. 6A that illustrates deactivating a dopant by exposing to chemical species in a portion of a solar cell according to one embodiment of the invention.

FIG. 6C is a view similar to FIG. 6B after deactivating a dopant by exposing to chemical species in a portion of a solar cell according to one embodiment of the invention.

FIG. 6D is an illustration of a cross-sectional view of a selective emitter solar cell according to one embodiment of the invention.

FIG. 7 illustrates an apparatus to deactivate a dopant in a portion of a solar cell according to one embodiment of the invention.

FIG. 8A is a graph illustrating an active boron concentration against a depth of a p-type doped region of an n-type silicon solar cell according to one embodiment of the invention.

FIG. 8B is a graph illustrating an active boron concentration against a depth from a surface of a p-type doped region of an n-type silicon solar cell according to one embodiment of the invention.

FIG. 8C is an illustration of a boron-hydrogen (“B—H”) passivation (“inactivation”) as a percentage of the electrically active boron versus depth according to one embodiment of the invention.

FIG. 9 is an illustration of a cross-sectional view of a selective emitter solar cell according to one embodiment of the invention.

FIG. 10 is an illustration of a cross-sectional view of a bifacial selective emitter solar cell having a grid line metallization on the back and a reduced rear-surface recombination velocity according to one embodiment of the invention.

FIG. 11 is a table view to compare conventional techniques to fabricate a solar cell having a selective emitter with a method to fabricate a solar cell according to one embodiment of the invention.

FIG. 12A is an illustration of a cross-sectional view of a portion of a solar cell according to one embodiment of the invention.

FIG. 12B is a view similar to FIG. 12A after a grid line is deposited onto a region of a solar cell according to one embodiment of the invention.

FIG. 13 illustrates an apparatus to deactivate a dopant in a portion of a solar cell according to one embodiment of the invention.

FIG. 14 shows an original boron profile and a hydrogenated profile based on experimental data according to one embodiment of the invention.

FIG. 15 shows a graph illustrating a collection efficiency of an emitter versus a surface recombination velocity according to one embodiment of the invention.

FIG. 16 shows a graph illustrating resistivity data versus a substrate temperature according to one embodiment of the invention.

FIG. 17 shows a graph illustrating increase in resistivity versus annealing temperature according to one embodiment of the invention.

FIG. 18 illustrates solar cells according to one embodiment of the invention.

### SUMMARY OF THE DESCRIPTION

Exemplary embodiments of methods and apparatuses to manufacture solar cells are described. A solar cell comprises a region formed on a substrate. The region has a dopant. In one embodiment, the region is a selective emitter of the solar cell. In one embodiment, the region is a back surface field of the solar cell. A grid line is deposited over a first portion of the doped region. A dopant profile is generated that has a concentration of electrically active dopants at a surface portion at the first portion of the region smaller than the concentration of electrically active dopants at a distance away from the surface portion. In an embodiment, an electrical activity of the dopant is deactivated in a second portion of the region outside the grid line. The grid line is used as a mask for deactivating the dopant.

In one embodiment, a method to manufacture a solar cell comprises deactivating an electrical activity of a dopant in a first portion of a region of the solar cell by exposure to chemical species using a grid line deposited on a second portion of the region as a mask. In one embodiment of the method, the region is an emitter formed on a solar cell substrate. In one embodiment of the method, the region is a back surface field of the solar cell. In one embodiment, the method further comprises generating a dopant profile having a concentration of active dopants at a surface portion of the first portion of the region smaller than the concentration of active dopants at a distance away from the surface portion. In one embodiment, the method further comprises depositing a passivation layer on the region, wherein the chemical species deactivates the dopant through the passivation layer. In one embodiment of the method deactivating comprises reacting the dopant with an atomic element of the chemical species; and forming an electrically inactive complex based on the reacting. In one embodiment, the method further comprises depositing an antireflective coating over the region, wherein the chemical species deactivates the dopant through the antireflective coating. In one embodiment of the method, the region has a p-type conductivity. In one embodiment of the method, the region has an n-type conductivity. In one embodiment of the method, the grid line is conductive. In one embodiment of the method, the electrical activity of the dopant in the second portion of the region underneath the grid line is substantially not deactivated. In one embodiment of the method, a total number of dopant particles in the region after deactivating is the same as the total number of dopant particles in the region prior to deactivating. In one embodiment of the method, the chemical species includes atomic hydrogen, deuterium, lithium, copper or a combination thereof, and deactivating comprises exposing the first portion of the region outside the grid line to the atomic hydrogen, deuterium, lithium, copper or a combination thereof. In one embodiment, the method further comprises generating a first concentration of active dopants at a surface portion of the first portion of the region, a second concentration of active dopants in the second portion of the region, and a third concentration of active dopants in the first portion of the region at a depth away from the surface portion. In one embodiment, the method further comprises supplying the chemical species to the first portion of the region of the solar cell placed in a chamber; generating atomic elements from the chemical species; and exposing the dopant in the first portion of the region to the atomic elements. In one embodiment of the method, the atomic elements are generated by plasma. In one embodiment of the method, the atomic elements are generated by water boiling. In one embodiment of the method, the atomic elements are generated by catalytically exposing a gas to a heated filament. In one embodiment, the method further comprises adjusting at least one of a temperature of the filament, geometry of the filament, a distance between the solar cell and the filament to control deactivating. In one embodiment, the method further comprises adjusting at least one of a pressure of the gas and a temperature in the chamber to control deactivating. In one embodiment of the method, deactivating is controlled by a geometry of a chamber. In one embodiment of the method, deactivating is controlled by time. In one embodiment of the method, the dopant is at least one of boron (B), aluminum (Al), gallium (Ga), indium (In), thallium (Tl). In one embodiment of the method, the dopant is at least one of nitrogen (N), phosphorus (P), arsenic (As), antimony (Sb), and bismuth (Bi). In one embodiment of the method, the grid line prevents the chemical species from reaching the second portion of the region of the solar cell. In one embodiment of the method, the grid line is deposited on the second portion of the region by screen printing that includes placing a metal paste containing an etchant over a passivation layer on the second portion of the region of the solar cell; and etching through the passivation layer down to the region by the etchant to place the metal paste into a direct contact with the second portion of region.

In one embodiment, a method to manufacture a solar cell comprises placing a solar cell into a chamber, the solar cell comprising at least one of an antireflective coating and a passivation layer on a first region on a substrate, the first region having a first dopant; and a first conductive grid line over a first portion of the first region; supplying a hydrogen gas through a heated filament into the chamber; generating at least one of atomic hydrogen and deuterium from the hydrogen gas; exposing the first portion of the first region to at least one of the atomic hydrogen and deuterium using a grid line as a mask to deactivate an electrical activity of the first dopant in the first portion of the first region of the solar cell. In one embodiment, the method further comprises forming an electrically inactive complex comprising the first dopant and at least one of the hydrogen atom and the deuterium atom in the exposed first portion. In one embodiment of the method, at least one of the atomic hydrogen and deuterium is generated by catalytic exposure of the hydrogen to the heated filament. In one embodiment of the method, the pressure in the chamber is from about 10 mTorr to about 10 Torr. In one embodiment of the method, the gas flow rate is about 20 sccm. In one embodiment of the method, the filament is heated to a temperature from about 16000 C to about 2100 0 C. In one embodiment of the method, a distance of the filament from the surface of the solar cell substrate is about 10 cm. In one embodiment, the method further comprises generating a dopant profile having a concentration of active dopants at a surface portion of the first portion of the first region smaller than the concentration of active dopants at a distance away from the surface portion.

In one embodiment, a solar cell comprises a first region formed on a first side of a substrate, the first region having a first dopant; and a first grid line over a first portion of the first region, wherein an electrical activity of a part of the first dopant is deactivated in a second portion of the first region outside the grid line. In one embodiment of the solar cell, the first dopant is distributed substantially uniformly in the second portion. In one embodiment of the solar cell, the portion of the first dopant is bound to chemical species and is electrically inactive. In one embodiment of the solar cell, the chemical species is at least one of atomic hydrogen, deuterium, lithium, and copper. In one embodiment of the solar cell, the region is a selective emitter formed on a solar cell substrate. In one embodiment of the solar cell, the region is a back surface field of the solar cell. In one embodiment of the solar cell, an electrically active first dopant concentration at a surface portion of the first portion is smaller than the electrically active first dopant concentration at a distance away from the surface portion. In one embodiment, the solar cell further comprises a passivation layer on the first region, wherein the grid line is in direct contact with the first portion of the first region. In one embodiment, the solar cell further comprises an antireflective coating over the first region. In one embodiment of the solar cell, the first dopant is electrically active in the first portion of the first region beneath the grid line. In one embodiment of the solar cell, the region is a p-type region. In one embodiment of the solar cell, the region is an n-type region. In one embodiment of the solar cell, the grid line forms an ohmic like contact with the first region. In one embodiment of the solar cell, the substrate includes at least one of a monocrystalline silicon and a polycrystalline silicon. In one embodiment, the solar cell further comprises a second region having a second dopant on a second side of the substrate; and a second grid line adjacent to the second region. In one embodiment of the solar cell, the electrical activity of the second dopant is deactivated in a portion of the second region.

In one embodiment, a solar cell, comprises a conductive grid line on a first portion of a first region on a first side of a substrate, wherein a concentration of active dopants at a first surface portion on a second portion of the first region outside the grid line is less than the concentration of active dopants at a distance away from the first surface portion. In one embodiment of the solar cell, the dopant is distributed substantially uniformly in the second portion. In one embodiment of the solar cell, a portion of the dopant is deactivated in the second portion of the first region. In one embodiment of the solar cell, the first region is a selective emitter on a solar cell substrate. In one embodiment of the solar cell, the first region is a back surface field of the solar cell. In one embodiment of the solar cell, the dopant is at least one of boron (B), aluminum (Al), gallium (Ga), indium (In), and thallium (Tl). In one embodiment of the solar cell, the dopant is at least one of nitrogen (N), phosphorus (P), arsenic (As), antimony (Sb), and bismuth (Bi). In one embodiment, the solar cell further comprises a passivation layer over the first region. In one embodiment of the solar cell, the active dopant concentration beneath the grid line is greater than the active dopant concentration outside the grid line. In one embodiment of the solar cell, the first region has a p-type conductivity. In one embodiment of the solar cell, the first region has an n-type conductivity. In one embodiment of the solar cell, the substrate includes at least one of a monocrystalline silicon and a polycrystalline silicon. In one embodiment, the solar cell further comprises a second region formed on a second side of the substrate; and a second grid line adjacent to the second region, wherein a dopant in a portion of the second region is deactivated. In one embodiment of the solar cell, the first surface portion comprises an intrinsic semiconductor layer. In one embodiment of the solar cell, the first surface portion comprises a lightly doped semiconductor layer having active dopant concentration less than about 10¹⁹ cm⁻³, and the second portion comprises heavily doped semiconductor layer having active dopant concentration more than 10¹⁹ cm⁻³. In one embodiment, a selective emitter solar cell comprises a solar cell substrate having a first dopant, wherein the solar cell substrate has a front surface and a back surface; an emitter having a second dopant at the front surface of the substrate; and a first conductive line on the emitter, wherein an electrical activity of at least one of the first dopant and the second dopant is deactivated. In one embodiment of the solar cell, the deactivated at least one of the first dopant and the second dopant is bound to chemical species and is electrically inactive. In one embodiment of the solar cell, the chemical species is at least one of atomic hydrogen, deuterium, lithium, and copper. In one embodiment of the solar cell the first dopant is a p-type dopant, and the second dopant is an n-type dopant. In one embodiment of the solar cell, the first dopant is an n-type dopant, and the second dopant is a p-type dopant. In one embodiment of the solar cell, an active second dopant concentration at a surface portion of the emitter outside of the first conductive line is less than the active second dopant concentration at a distance away from the surface portion of the emitter. In one embodiment of the solar cell, at least one of the first dopant and the second dopant is distributed substantially uniformly. In one embodiment, the solar cell further comprises a second conductive line on the back surface of the substrate, wherein the first dopant concentration at the back surface outside the second conductive line is less than the first dopant concentration at a distance away from the back surface. In one embodiment, the solar cell further comprises a passivation layer on the emitter. In one embodiment, the solar cell further comprises an antireflective coating on the emitter. In one embodiment, the solar cell further comprises a passivation layer on the back surface of the substrate. In one embodiment, the solar cell further comprises a third conductive line on the emitter.

In one embodiment, a method to manufacture a solar cell comprises generating a dopant profile having a concentration of active dopants at a first surface portion on a first portion of a region of solar cell smaller than the concentration of active dopants at a distance away from the surface portion, wherein a grid line is on a second portion of the region of the solar cell. In one embodiment of the method, the region is an emitter formed on a solar cell substrate. In one embodiment of the method, the region is a back surface field of the solar cell. In one embodiment of the method, the first portion has the first surface portion, and wherein the dopant profile is generated by deactivating an electrical activity of a dopant at the first surface portion of the first portion of the region of the solar cell by exposure to chemical species. In one embodiment of the method, the dopant profile is generated by depositing a semiconductor layer onto the first portion of the region of the solar cell, the semiconductor layer having the first surface portion, wherein the concentration of active dopants at the first surface portion is less than the concentration of active dopants in the first portion. In one embodiment, the method further comprises depositing a passivation layer onto the semiconductor layer. In one embodiment, the method further comprises etching through any of layers (e.g., the passivation layer, AR layer, or both) above the semiconductor layer until a contact resistance with the grid line of less than 1 ohm×cm² is achieved.

Other features of the embodiments of the invention will be apparent from the accompanying drawings and from the detailed description which follows.

### DETAILED DESCRIPTION

Methods and apparatuses to manufacture solar cells are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as semiconductor deposition techniques are not described in detail in order to not unnecessarily obscure embodiments of the present invention. Furthermore, it is to be understood that the various embodiments shown in the Figures are illustrative representations and are not necessarily drawn to scale.

Disclosed herein are methods of fabricating solar cells. In one embodiment, a method to manufacture a solar cell comprises deactivating an electrical activity of a dopant in a first portion of a region of the solar cell by exposure to chemical species. A grid line deposited on the region is used as a mask for deactivating. A dopant profile is generated by deactivating. The dopant profile has a concentration of electrically active dopants at a surface portion of the region smaller than the concentration of electrically active dopants at a distance away from the surface portion.

Also disclosed herein are solar cells. A solar cell comprises a region formed on a substrate. The region has a dopant. A grid line is deposited over a first portion of the region. An electrical activity of a portion of the dopant is deactivated in a second portion of the region outside the grid line. The grid line is used as a mask for deactivating the dopant. A dopant profile is generated that has a concentration of electrically active dopants at a surface portion of the first portion of the region smaller than the concentration of electrically active dopants at a distance away from the surface portion. In one embodiment, the region is a selective emitter formed on the solar cell substrate. In one embodiment, the region is a back surface field of the solar cell.

In accordance with at least some embodiments, solar cells are N-type and P-type solar cells having the deactivated regions as described herein. In some embodiments, a reduction in the sheer number of process operations is achieved by using process flows described herein, as compared with conventional process flows.

In an embodiment, fabrication of the selective emitter solar cells involves a one step, self-aligned process that requires few consumables, and achieves an electrically active dopant concentration at a surface portion of the selective emitter between the grid lines as low as possible. In at least some embodiments, the selective emitter solar cell fabricated using processes as described herein has only marginally increased sheet resistance and requires the same or fewer grid lines as homogeneous emitter solar cells.

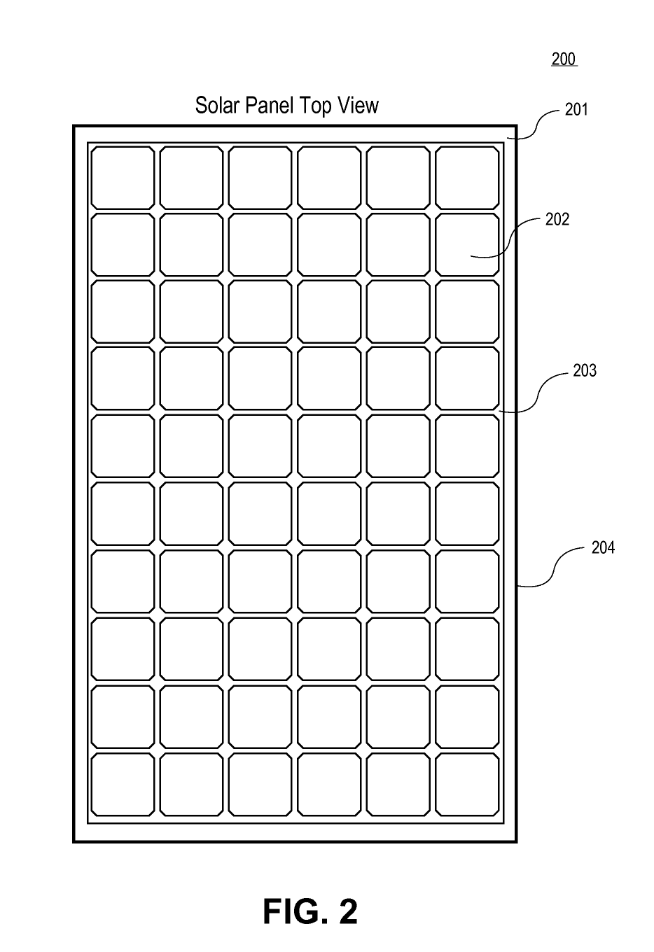

FIG. 2 is an illustration of a solar cell panel top view according to one embodiment of the invention. A solar cell panel 200 has a frame 201 that holds solar cells, such as a solar cell 202. In an embodiment, the solar cell has grid lines and at least one of a selective emitter and a back surface field (not shown) fabricated using processes as described herein. In an embodiment, the solar cell is formed on a semiconductor wafer or substrate which is a thin slice of semiconductor material, e.g., silicon, or other semiconductor material. In one embodiment, the wafer serves as the substrate for the solar cell built in and over the wafer.

In an embodiment, the solar cell is an n-type solar cell having a self-aligned p-type selective emitter as described in further detail below. In an embodiment, the solar cell is a p-type bifacial solar cell having an n-type selective emitter and a self-aligned p-type back surface field to absorb light from both sides as described in further detail below.

The solar cells, such as solar cell 202 are mounted between a front glass sheet 203 and a back sheet 204. In one embodiment, the frame 201 is an aluminum frame, titanium frame, or other metal frame. In one embodiment, the back sheet is a plastic sheet, a metal sheet, or a combination thereof. In one embodiment, the back sheet is a glass sheet. In an embodiment, solar cells of the solar cell panel are electrically connected to each other to produce a desired voltage. The front glass sheet is typically made of a tempered glass to allow light to pass while protecting the semiconductor wafers from abrasion and impact due to e.g., wind-driven debris, rain, hail, etc. In an embodiment, solar cells are connected in series to create an additive voltage. In an embodiment, the front of one solar cell is connected in series to a back of the adjacent cell by a wire, a wire ribbon, or both. In an embodiment, strings of cells connected in series are handled independently. In an embodiment, solar cells are connected in parallel to yield a high current. In an embodiment, to make practical use of the solar-generated energy, the electricity is fed into an electricity grid using inverters (grid-connected photovoltaic systems). In a stand-alone system, a battery is used to store the energy that is not needed immediately. Solar panels can be used to power or recharge portable devices. In an embodiment, the solar cells in the panel are electrically interconnected by flat wires, metal ribbons, or both.

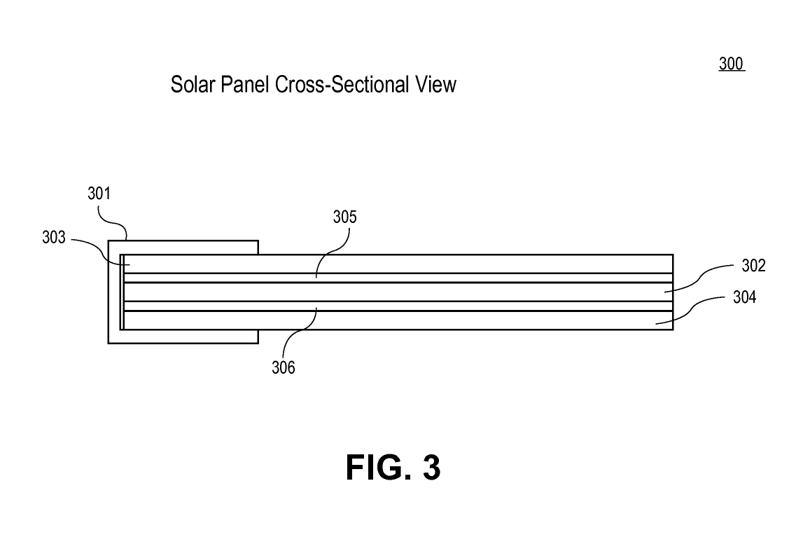

FIG. 3 is an illustration of a cross-sectional view 300 of a portion of a solar cell panel 300 according to one embodiment of the invention. In an embodiment, the view 300 illustrates a portion of the panel 200 as depicted in FIG. 2. As shown in FIG. 3, a metal frame 301 embraces a stack comprising a solar cell 302 placed between a front glass sheet 303 and a back sheet 304. In an embodiment, the solar cell has grid lines and at least one of a selective emitter and a back surface field (not shown) fabricated using processes as described herein. An encapsulant 305 is placed between the front surface of the solar cell 302 and front glass sheet 303. An encapsulant 306 is placed between back surface of the solar cell 302 and back sheet 304. In an embodiment, each of the encapsulants 305 and 306 is a polymer encapsulant.

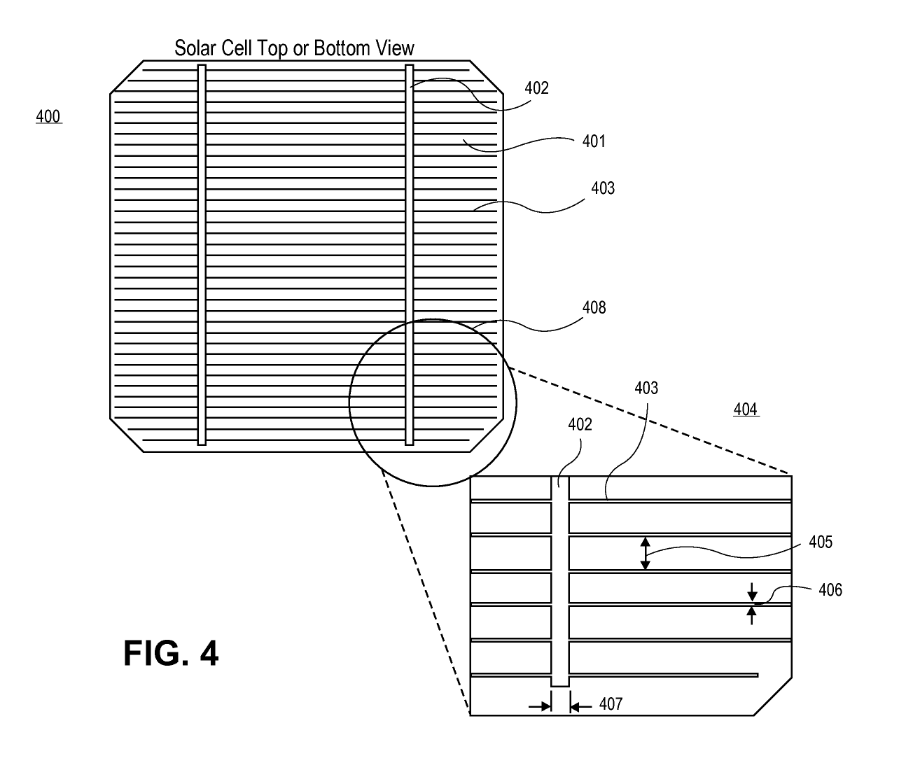

FIG. 4 is an illustration of a view of a solar cell 400 having grid lines according to one embodiment of the invention. The solar cell can be one of the solar cells 202 and 320 as depicted in FIGS. 2 and 3. In one embodiment, the view 400 is a top view of the solar cell. In one embodiment, view 400 is a bottom view of the solar cell. The solar cell has grid lines, such as a grid line 403, and bus bars, such as a bus bar 402 formed on the surface of the solar cell substrate 401. A view 404 is an enlarged view of a portion 408 of the solar cell. In one embodiment, the grid lines and bus bars are conductive lines comprising silver, copper, other metal, any other electrically conductive material, or a combination thereof.

The grid lines are used to collect current, voltage, or both from portions of a solar cell. The grid lines are connected to a bus bar. The bus bar is typically used to collect current, voltage, or both from multiple solar cells. In an embodiment, the spacing 405 between the grid lines is greater than about 1.8 millimeters (“mm”). In one embodiment, the spacing between the grid lines is from about 1.5 mm to about 25 mm. In more specific embodiment, the spacing between the grid lines is about 1.9 mm. In an embodiment, the width 406 of the grid line is from about 80 microns (“μm”) to about 100 μm. In an embodiment, the width 407 of the bus bar is from about 1.5 mm to about 4 mm. In more specific embodiment, the width 407 of the bus bar is about 2 millimeters. In an embodiment, a 6-inch solar cell semiconductor substrate or wafer has from about 80 to about 90 grid lines formed thereon. In an embodiment, a density of the grid lines over the solar cell substrate is not more than about 13 grid lines per inch. In other embodiment, a density of the grid lines over the solar cell substrate is less than about 10 grid lines per inch. In an embodiment, the solar cell substrate is a semiconductor, for example, monocrystalline silicon, polycrystalline silicon, amorphous silicon, cadmium telluride, copper indium selenide/sulfide, gallium arsenide, other semiconductor, or a combination thereof. In an embodiment, the solar cell substrate includes a thin film, e.g., amorphous silicon, cadmium telluride, copper indium gallium selenide, gallium arsenide, or other semiconductor thin film deposited on a supporting substrate. In one embodiment, the solar cell substrate is fabricated at least in part using a top-down aluminum induced crystallization (TAIC). In an embodiment, the solar cell substrate includes an organic material, e.g., dye, a polymer, or a combination thereof.

In an embodiment, the fine conductive grid lines and wider bus bars are screen-printed onto the surface of the semiconductor substrate using a metal paste. In one embodiment, metal paste includes silver, copper paste, other metal, other electrically conductive material, or a combination thereof. In one embodiment, the metal paste is a silver paste. In one embodiment, the solar cell substrate has a grid pattern contact on the front side and on the back side. In one embodiment, the solar cell substrate has a grid pattern on the front side and a full area metal contact on the back surface (not shown). The full area metal contact typically covers the entire rear side of the substrate. In an embodiment, the full area rear contact is formed by screen-printing a metal paste, e.g., aluminum. Typically, the paste is then annealed at several hundred degrees Celsius to form metal electrodes in ohmic like contact with the silicon. After the metal contacts are made, the solar cells are interconnected by flat wires or metal ribbons, and assembled into modules or solar panels, such as a solar cell panel depicted in FIG. 2.

The conductive grid lines and bus bars may be deposited over the solar cell substrate using one of conductive line deposition techniques known to one of ordinary skill in the art of electronic device manufacturing.

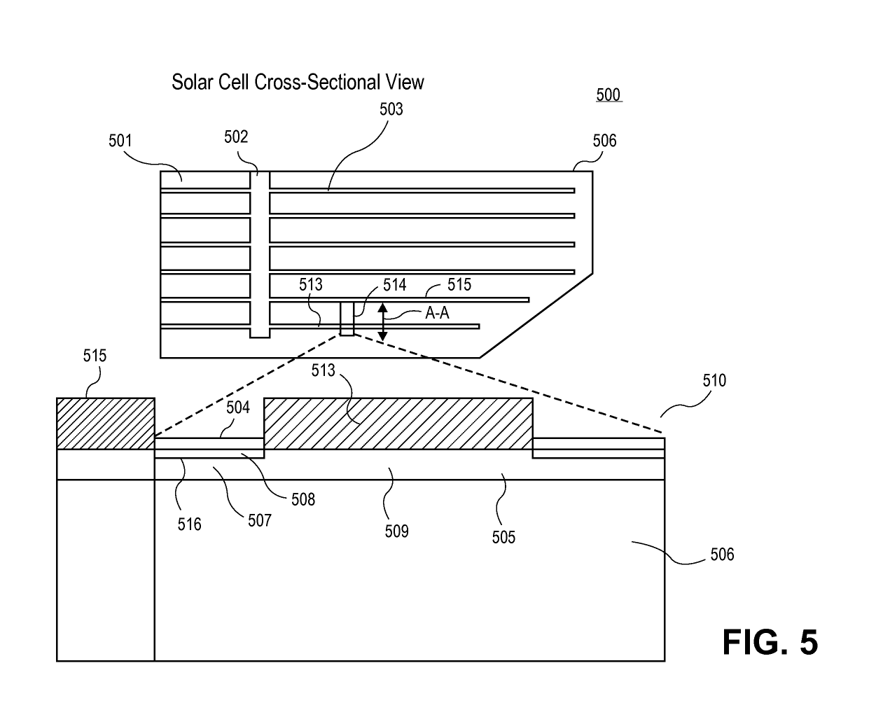

FIG. 5 is an illustration of a portion of a solar cell according to one embodiment of the invention. A solar cell 500 can be one of the solar cells as depicted in FIGS. 2, 3, and 4. A portion 501 of solar cell 500 includes a bus bar 502 and grid lines, such as a grid line 503 and a grid line 513 formed over a solar cell substrate 506, as described above with respect to FIGS. 2, 3, and 4. A view 510 is a cross-sectional view of a portion 514 of the solar cell along an axis A-A. The solar cell includes a doped region 505 formed on substrate (“base”) 506. Typically, the type of the solar cell is defined by the type of the base. In an embodiment, the solar cell substrate is a semiconductor substrate, for example, monocrystalline silicon, polycrystalline silicon, amorphous silicon, cadmium telluride, copper indium selenide/sulfide, gallium arsenide, other semiconductor, or a combination thereof substrate.

In one embodiment, the region 505 is a selective emitter of the solar cell fabricated using methods as described herein. In an embodiment, the doped region has a conductivity type that is different from the conductivity type of the substrate. For example, if the substrate has an n-type conductivity, the doped region has a p-type conductivity. If the substrate has a p-type conductivity, the doped region has an n-type conductivity. In an embodiment, the base region is an n-type silicon substrate and the doped region has a p-type dopant, e.g., boron (B), aluminum (Al), gallium (Ga), indium (In), thallium (Tl), other acceptor dopant, or a combination thereof to provide a p-type conductivity. In an embodiment, the base region is a p-type silicon substrate, and the doped region has an n-type dopant, e.g., nitrogen (N), phosphorus (P), arsenic (As), antimony (Sb), bismuth (Bi), other donor dopant, or a combination thereof to provide n-type conductivity. In one embodiment, the doped region is a p⁺-type region having an acceptor dopant concentration of at least about 10¹⁹ cm⁻³. In one embodiment, the doped region is an n⁺-type region having a donor dopant concentration of at least about 10¹⁹ cm⁻³.

In an embodiment, the doped region is formed by introducing the dopant into the substrate by diffusion, ion implantation, or any other techniques known to one of ordinary skill in the art of the electronic device manufacturing. In an embodiment, the doped region is formed by one of epitaxial techniques known to one of ordinary skill in the art of electronic device manufacturing.

A grid line 513 is deposited on the doped region 505. In an embodiment, the grid line forms an ohmic like contact with the doped region. In an embodiment, prior to forming the grid line, a passivation layer 504 is formed on the doped region 505 to reduce amount of the surface traps for carriers (electrons and/or holes). In an embodiment, prior forming the passivation layer, the doped region on the silicon substrate having a (100) crystalline plane orientation, is etched predominantly along a (111) crystalline plane orientation to form pyramids (not shown) to trap the incident light. In one embodiment, the height of the pyramids on the surface of the doped region 505 is about 10 microns. In an embodiment, the doped region is etched using one of wet or dry etching techniques known to one of ordinary sill in the art of electronic device manufacturing.

In an embodiment, the passivation layer is a silicon nitride deposited on the pyramids formed on the surface of the doped silicon region. In one embodiment, the passivation layer is deposited at a temperature less than about 200° C. In an embodiment, the passivation layer is deposited onto the doped region using a plasma-enhanced chemical vapor deposition (PECVD) technique, or one of other passivation layer deposition techniques known to one of ordinary skill in the art of electronic device manufacturing.

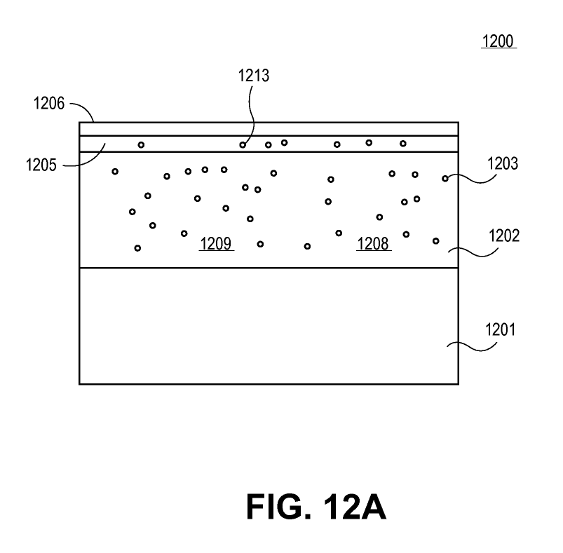

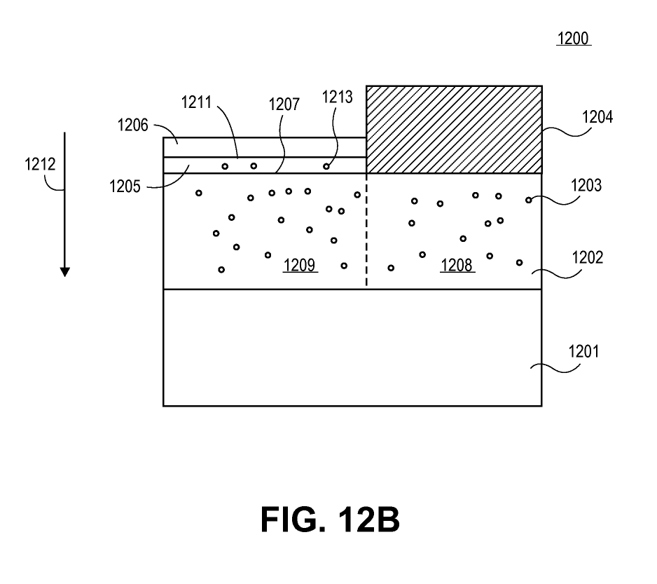

In an embodiment, an anti-reflective (“AR”) coating (not shown) is deposited on the passivation layer to reduce light loss due to reflection and to direct the light into the solar cell. In an embodiment, the AR coating is a multilayer coating. In an embodiment, the passivation layer 504 is an AR coating. In an embodiment, the passivation layer is silicon nitride, silicon oxide, aluminum oxide, or a combination thereof. In one embodiment, the AR coating is deposited using a plasma-enhanced chemical vapor deposition (PECVD) technique, or one of other AR coating deposition techniques that are known to one of ordinary skill in the art of electronic device manufacturing. In an embodiment, a thin semiconductor layer (not shown) is formed on the surface 508 of a portion 507 of the doped region 505 outside the grid line 513. In an embodiment, the passivation layer 504 acting as an AR coating is formed on top of the semiconductor layer, as described in further detail below with respect to FIG. 12. In an embodiment, the electrically active dopant concentration in the semiconductor layer deposited onto the surface 508 of the portion 507 is one or more orders of magnitude lower than the electrically active dopant concentration in the doped region 505, as described in further detail below with respect to FIG. 12.

In an embodiment, depositing a grid line onto the doped region includes screen printing a metal paste containing an etchant onto the AR layer, passivation layer, or both. The etchant in the metal paste etches through the AR layer, passivation layer, or both down to the doped region so that the metal paste is placed in direct contact with the doped region. In an embodiment, the metal paste containing an etchant is silver, aluminum, or any other metal paste known to one of ordinary skill in the art of electronic device manufacturing. In one embodiment, the silver paste screen printed onto the doped region of the silicon solar cell substrate is heated to about 700° C. to etch through the AR layer, passivation layer, or both down to the doped silicon region.

As shown in FIG. 5, region 505 has portion 507 that is not covered by the grid line 513 and a portion 509 covered by grid line 513. In an embodiment, an electrical activity of the dopant in the portions of the doped region that are outside of the grid line coverage, such as portion 507 is deactivated by exposing to chemical species, as described in further detail below.

In an embodiment, the portion 507 has a concentration of electrically active dopants at a surface 508 smaller than the concentration of electrically active dopants at a distance 516 away from the surface 508. In an embodiment, the dopant is substantially not deactivated in portion 509 beneath the grid line 513, as described in further detail below.

In one embodiment, the doped region 505 is a back surface field of the solar cell fabricated using methods as described herein. In an embodiment, the doped region has the same conductivity type as the substrate. For example, if the substrate has a p-type conductivity, the doped region has a p-type conductivity. In an embodiment, the doped region on the p-type silicon substrate has a p-type dopant, e.g., boron (B), aluminum (Al), gallium (Ga), indium (In), thallium (Tl), other acceptor dopant, or a combination thereof to provide a p-type conductivity. If the substrate has an n-type conductivity, the doped region has an n-type conductivity. In an embodiment, the doped region on the n-type silicon substrate has an n-type dopant, e.g., nitrogen (N), phosphorus (P), arsenic (As), antimony (Sb), bismuth (Bi), other donor dopant, or a combination thereof to provide n-type conductivity.

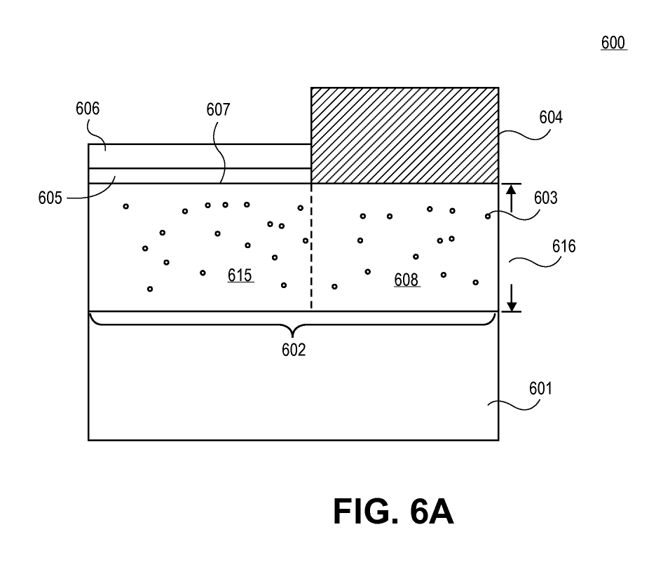

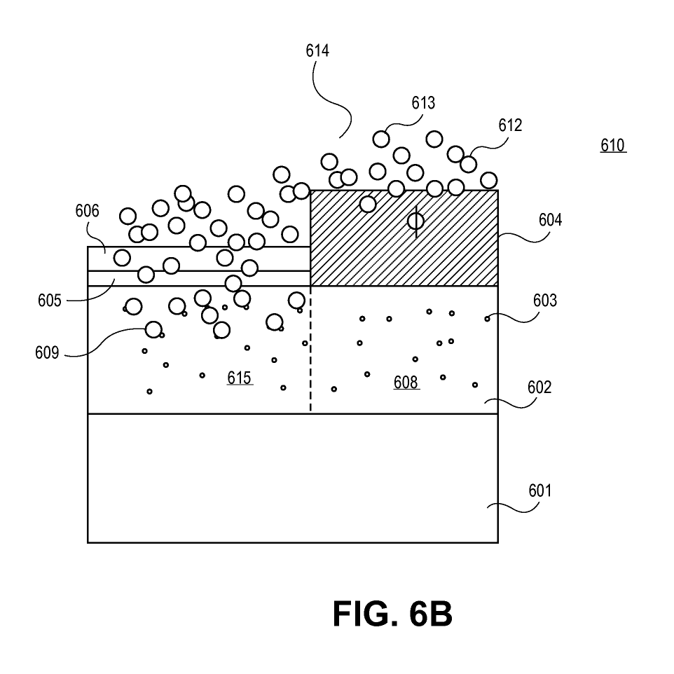

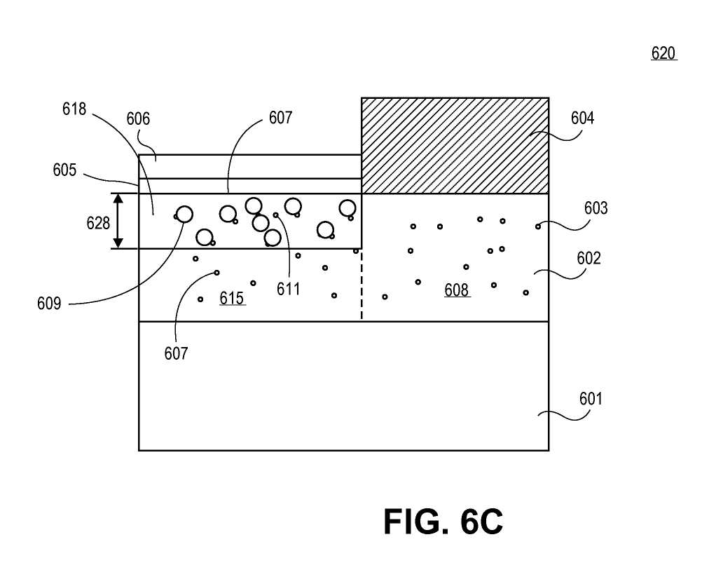

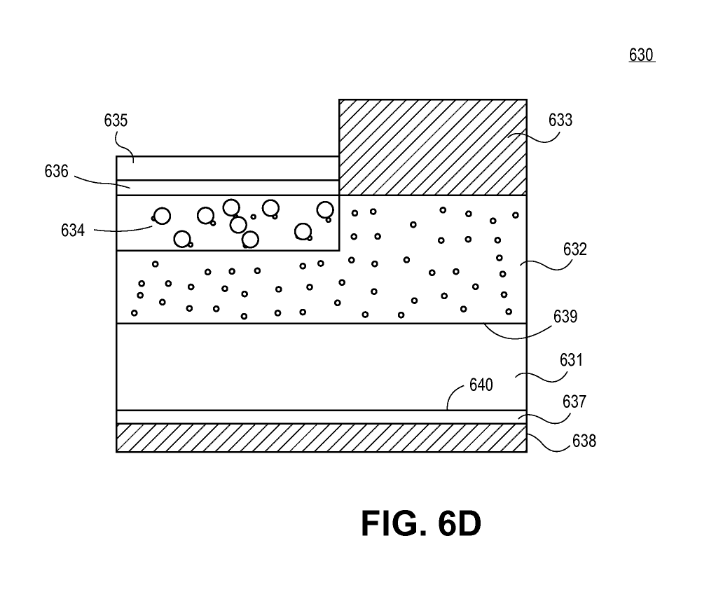

FIG. 6A is an illustration of a cross-sectional view of a portion of a solar cell in a partially fabricated state according to one embodiment of the invention. A portion of a solar cell 600 can be one of the solar cells as depicted in FIGS. 2, 3, 4, and 5. A region 602 is formed on a substrate. In one embodiment, the substrate includes at least one of a monocrystalline silicon and a polycrystalline silicon, or any other material as described above. Region 602 has a dopant. The dopant is represented by a plurality of electrically active dopant particles, such as an active dopant particle 603. Depending on embodiment, the electrically active dopant particle is an electron, hole, atom, ion, or any other electrically active particle of the dopant. In one embodiment, the doped region 602 is a selective emitter of the solar cell. In one embodiment, the thickness 616 of the region 602 is from about 0.001 μm to about 0.5 μm. In one embodiment, the region 602 is a back surface field of the solar cell. In one embodiment, the doped region has a p-type conductivity. In one embodiment, the doped region has an n-type conductivity. In one embodiment, the dopant is at least one of boron (B), aluminum (Al), gallium (Ga), indium (In), thallium (Tl), and other acceptor dopant. In one embodiment, the dopant is at least one of nitrogen (N), phosphorus (P), arsenic (As), antimony (Sb), bismuth (Bi) and other donor dopant.

The region 602 has a portion 608 and a portion 615. A conductive grid line 604 is deposited on the portion 608 of region 602. The grid line forms an ohmic like contact with the doped region. The portion 615 is outside the grid line. As shown in FIG. 6A, the active dopant particles are distributed substantially uniformly in region 602 that includes portion 608 beneath the grid line 604 and portion 615 outside the grid line. A passivation layer 605 is formed on a surface 607 of region 602. In one embodiment, the thickness of the passivation layer is from about 10 nanometers (“nm”) to about 200 nm. In more specific embodiment, the thickness of the passivation layer is from about 70 nm to about 100 nm. In an embodiment, the passivation layer 605 is silicon nitride. In an embodiment, the passivation layer 605 is silicon oxide. In an embodiment, the passivation layer 605 is aluminum oxide. In an embodiment, an antireflective (“AR”) coating is formed on the passivation layer 605, as described above. In an embodiment, the passivation layer 605 acts as an AR coating, as described above. In one embodiment, the thickness of the AR coating is from about 10 nm to about 200 nm. In one embodiment, the thickness of the AR coating is less than about 100 nm. In one embodiment, the thickness of the AR coating is from about 20 nm to about 100 nm. In one embodiment, the total thickness of both the passivation layer and the AR coating is from about 10 nm to about 400 nm. In an embodiment, the thickness of the grid line is from about 5 μm to about 200 μm. In an embodiment, the thickness of the grid line is from about 5 μm to about 45 μm. In an embodiment, the grid line is at least four times thicker than the AR coating and/or passivation layer.

FIG. 6B is a view 610 similar to FIG. 6A that illustrates deactivating a dopant by exposing to chemical species in a portion of a solar cell according to one embodiment of the invention. As shown in FIG. 6B, a portion of the solar cell covered by the AR coating 606 on passivation layer 605 outside the grid line 604 is exposed to chemical species 614. Chemical species 614 comprises atomic elements, such as an atomic element 613, and diatomic elements, such as a diatomic element 612. As shown in FIG. 6B, the atomic element of the chemical species generated from a source is exposed to a surface of the solar cell. The atomic element (e.g., atomic hydrogen, deuterium, lithium, copper or other atomic element) can be generated from the chemical species (e.g., hydrogen gas) in various ways, e.g., using plasma, water boiling, and catalytic exposure of a gas to a heated filament. In one embodiment, the material used for the filament is tungsten, tantalum, or a combination thereof.

The atomic element is blocked by the screen printed gridline 604, but penetrates the anti-reflective coating 606 and passivation layer 605 to react with the dopant. That is, the grid line acts a mask for deactivating the dopant. In one embodiment, the grid line has enough thickness to prevent the atomic elements of chemical species from penetrating the underlying region of the solar cell. The atomic element, e.g., atomic element 613 penetrates through AR coating 606 and passivation layer 606, reacts with the dopant, and forms an electrically inactive complex with the dopant, such as an electrically inactive complex 609. In an embodiment, the electrically inactive complex comprises the dopant particle bound to the atomic element of the chemical species. In one embodiment, the electrically inactive complex comprises a current carrier associated with the dopant (e.g., hole, electron) captured by the atomic element.

In an embodiment, the chemical species includes atomic hydrogen, deuterium, lithium, copper or other atomic element. The dopant is deactivated by exposing the portion of the region outside the grid line to atomic hydrogen. In an embodiment, for a p⁺-type silicon region of the solar cell having boron, or any other acceptor dopant exposed to an atomic hydrogen chemical species, the electrically inactive complex is formed that comprises a hole captured by the atomic hydrogen. In an embodiment, for a n⁺-type silicon region of the solar cell having phosphorous, or any other donor dopant exposed to an atomic hydrogen chemistry, the electrically inactive complex is formed that comprises an electron captured by the atomic hydrogen. In an embodiment, the atomic hydrogen reacts with the silver material of the grid line instead of penetrating through the grid line without reaching the underlying portion of the region of the solar cell, e.g., portion 608.

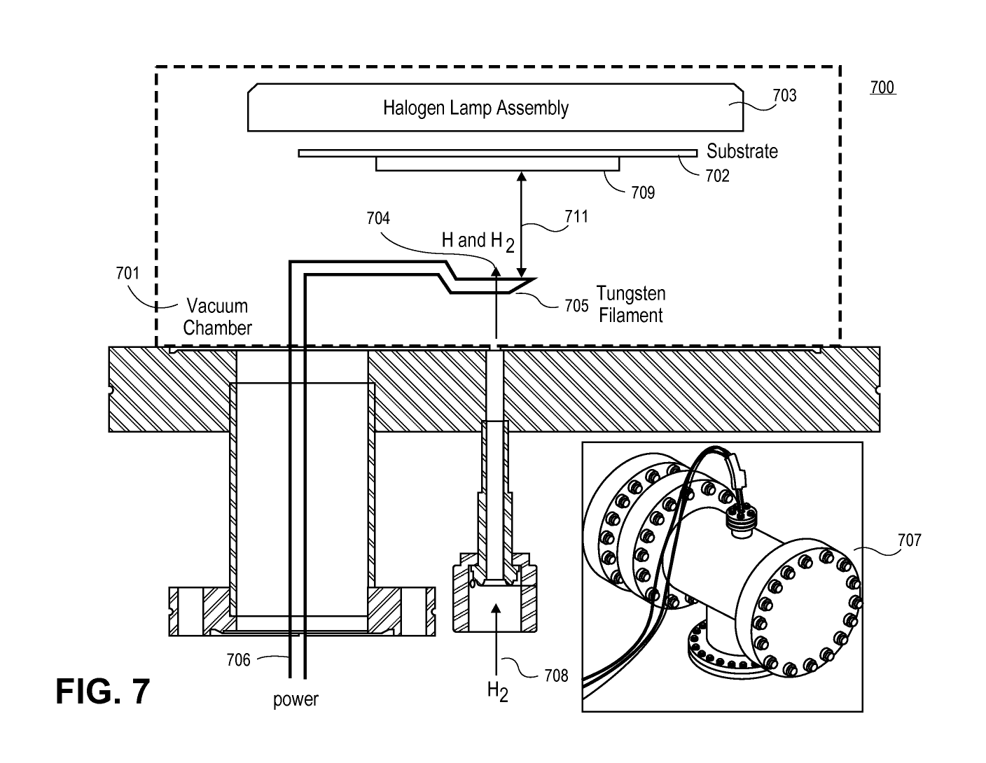

FIG. 7 illustrates an apparatus to deactivate a dopant in a portion of a solar cell according to one embodiment of the invention. An apparatus 700 includes a vacuum chamber 701, an inlet 708 to supply a gas containing chemical species, e.g., hydrogen, deuterium, or other chemical species, and a power supply 706, a filament 705, a lamp assembly 703, and a substrate 702 to hold a portion of solar cell. As shown in FIG. 7, a gas 704 comprising the chemical species (e.g., hydrogen has) is supplied through an inlet 708 to a solar cell 709 placed on a substrate 702 at a distance 711 from filament 705. Atomic elements (e.g., hydrogen atoms H, deuterium atoms D, or other atomic elements) are generated from the gas. The dopant in the portion of the region of the solar cell 709 not covered by the grid line is exposed to the atomic elements. In one embodiment, at least one of a temperature of the filament, a geometry of the filament, a distance between the solar cell and the filament are adjusted to control deactivating. In at least some embodiment, at least one of a pressure and a temperature of the gas in the chamber is adjusted to control deactivating. In one embodiment, deactivating a dopant in a portion of a solar cell is controlled by a geometry of the chamber. In one embodiment, deactivating a dopant in a portion of a solar cell is controlled by exposure time.

In one embodiment, a hydrogenation apparatus to deactivate a dopant in a portion of a solar cell has a stainless steel body with about 8 inches conflate flanges in a T-shape. The system is connected to a larger chamber which provides exhaust for hydrogen gas through standard mechanical pumps, as shown in an insert 707. The hydrogen is supplied from a gas cylinder through ¼ inches stainless steel tubing to a mass flow controller (MFC) (not shown). The MFC controls the flow rate of hydrogen directly to the hydrogenation chamber, e.g., chamber 701. Once in the chamber, the pressure is detected by a sensor and controlled at the exhaust with a pressure controller which opens or closes a throttle valve. In one embodiment, a pressure range used for hydrogenation is from about 10 mTorr to about 10 Torr. In one embodiment, the flow rate of the hydrogen gas is from about 10 to about 30 standard cubic centimeters per minute (sccm). In one embodiment, the flow rate of the hydrogen gas is about 20 sccm.

At a controlled pressure and flow rate, a gas 704 (e.g., hydrogen gas) enters the chamber directly below the filament 705 (e.g., tungsten filament). In an embodiment, hydrogen gas enters the chamber from a gas line tapped in the bottom-center directly underneath the center of the substrate. Hydrogen molecules (H₂) striking the tungsten filament dissociate creating an atmosphere of atomic hydrogen and H₂. In an embodiment, depending on the filament temperature, a certain fraction of the H₂ is dissociated into atomic hydrogen. Other factors controlling atomic hydrogen flux at the sample surface are pressure, filament geometry, filament-substrate distance, and chamber geometry. In one embodiment, the filament is heated to a temperature in a range between about 1600° C. to 2100° C. In one embodiment, the 1900° C. tungsten filament is approximately 10 cm from the surface of the substrate.

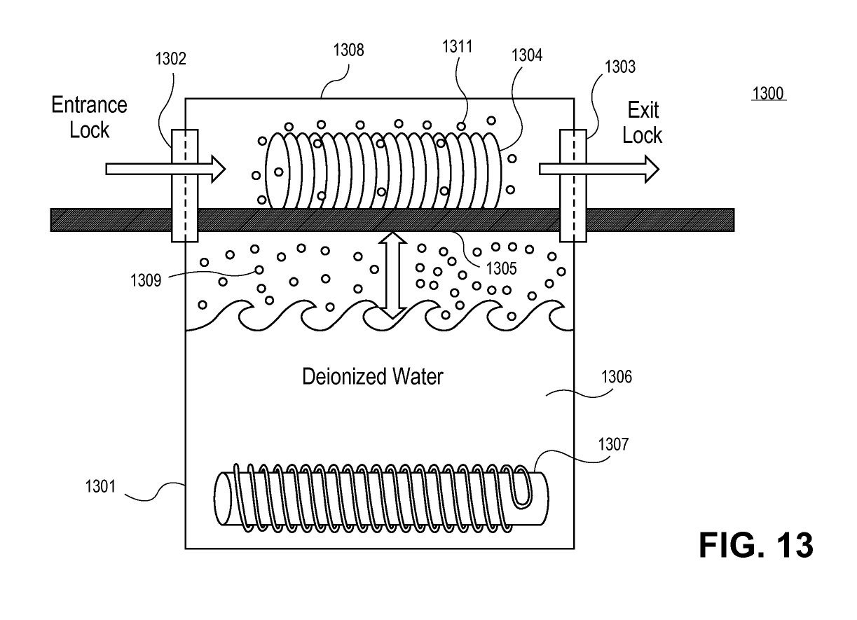

FIG. 13 illustrates an apparatus 1300 to deactivate a dopant in a portion of a solar cell according to one embodiment of the invention. An apparatus 1300 includes an autoclave container 1301 having an entrance lock 1302, an exit lock 1303, and a heating element 1307. In an embodiment, heating element is a resistive electric heating element. Deionized water 1306 is placed in the container 1301. In one embodiment, one or more solar cells 1304 are placed on a holder 1305 above the surface of the water 1306, as shown in FIG. 13. In one embodiment, one or more solar cells 1304 are placed into the water 1306. In one embodiment, deactivating the dopant in the portion of the solar cell involves submerging the solar cell into the deionized water.

A lid 1308 with a pressure release valve is secured on the top of the container 1301. In one embodiment, the pressure in container is greater than 1 atm. In one embodiment, the pressure in the container is about 2 atm. In one embodiment, the pressure in container 1301 is from about 15 pound per square inch (“psi”) to about 30 psi. In more specific embodiment, the pressure in chamber 1301 is about 15 psi. Heating element 1307 boils the pressurized deionized water 1304 in the container 1301. Due to the pressure, the water boiling temperature is raised above 100 degrees Celsius (“° C.”). In one embodiment, the water boiling temperature in the chamber 1301 is from about 120° C. to about 150° C. Atomic elements, e.g., an atomic element 1309 and an atomic element 1311 of the chemical species (e.g., hydrogen H, deuterium D, or other chemical species) are generated by the pressurized water boiling. The dopant in the portion of the region of the solar cell not covered by the grid line is exposed to the atomic elements, such as atomic element 1311, as described herein. In one embodiment, at least one of a pressure in the container, a temperature of the boiling water, a geometry of the container, a distance between the solar cell and the surface of the water are adjusted to control deactivating of the dopant. In one embodiment, deactivating a dopant in a portion of the solar cell is controlled by exposure time of the solar cell to the atomic elements.

In one embodiment, the apparatus to manufacture a solar cell using the water boiling apparatus as described herein is about 15 times cheaper than that of using the vacuum chamber with a heated filament as described herein.

FIG. 6C is a view 620 similar to FIG. 6B after deactivating a dopant by exposing to chemical species in a portion of a solar cell according to one embodiment of the invention. It should be understood that the FIG. 6C is an illustrative representation and is not necessarily drawn to scale, as noted above regarding the drawings described herein. As shown in FIG. 6C, a dopant profile is generated that has a concentration of active dopant particles, such as an active dopant particle 611 in a surface portion 618 at surface 607 of the portion 615 of the region 602 not covered by the grid line 604 smaller than a concentration of active dopant particles at a distance 628 away from the surface portion 618. As shown in FIG. 6C, the electrical activity of the dopant in the portion 608 of the region underneath the grid line 604 is substantially not deactivated, and concentration of the active dopant particles, such as active dopant particle 603 in that region remains the same. In one embodiment, after deactivating, a total number of dopant particles including electrically active dopant particles and electrically deactivated dopant particles in the portion 615 of the region 602 outside the grid line 604 is the same as the total number of dopant particles in that portion prior to deactivating. In one embodiment, after deactivating the dopant by atomic hydrogen (hydrogenation), the active boron concentration outside of the grid lines is drastically reduced because around 99% of the boron at the surface of the doped region, such as surface 607, is inactivated. Below the grid line, the active boron concentration does not change substantially because atomic hydrogen is blocked by the screen-printed grid line. As shown in FIG. 6C, surface portion 618 of the portion 615 of the region 602 not covered by grid line 604 has a concentration of electrically active dopants, such as electrically active dopant 611, that is smaller than a concentration of electrically active dopants, such as electrically active dopant 617 at a depth 628 away from the surface 607. In one embodiment, depth 628 is less than 0.1 μm. In one embodiment, depth 628 is from about 0.001 μm to about 0.1 μm. In one embodiment, depth 628 is from about 0.001 μm to about 0.05 μm. The concentration of electrical active dopants in surface portion 618 of the region 602 not covered by grid line 604 is smaller than a concentration of electrically active dopants, such as electrically active dopant 603 in a portion 608 of the region 602 underneath the grid line 604. In one embodiment, the electrically active dopant concentration beneath the grid line is more than one order of magnitude greater than the electrically active dopant concentration at the surface portion of the region of the solar cell outside the grid line. In one embodiment, the electrically active dopant concentration beneath the grid line is at least two orders of magnitude greater than the electrically active dopant concentration at the surface portion of the region of the solar cell outside the grid line. In an embodiment, the electrically active dopant concentration at the surface portion of the region of the solar cell outside the grid line is one or more orders of magnitude smaller than the electrically active dopant concentration at the portion of the region of the solar cell outside the grid line at a distance away from the surface portion. In an embodiment, the electrically active dopant concentration at the surface portion of the region of the solar cell outside the grid line is at least two orders of magnitude smaller than the electrically active dopant concentration at the portion of the region of the solar cell outside the grid line at a distance away from the surface portion. In one embodiment, 99% of dopants are inactive in the surface portion of the region of the solar cell outside the grid line, such as surface portion 618. In one embodiment, the electrically active dopant concentration beneath the grid line is at least 10²⁰ cm⁻³, the electrically active dopant concentration at the surface portion of the region of the solar cell outside the grid line is from about 10¹⁷ cm⁻³ to about 5×10¹⁸ cm⁻³, and the electrically active dopant concentration at the portion of the region of the solar cell outside the grid line at a distance away from the surface portion is at least 10²⁰ cm⁻³. In one embodiment, the hydrogenated selective emitter obtained by exposing the homogeneous emitter to atomic hydrogen has drastically reduced active acceptor concentration in the surface portion (e.g., 99% dopants are inactive). This provides low series resistance and low surface recombination that enables higher Voc and Jsc without increasing series resistance enough to require more surface metallization.

In one embodiment, atomic hydrogen inactivates the electrical activity of acceptor impurities in silicon e.g., boron, aluminum, and other acceptor impurities. Exposing silicon to atomic hydrogen can have several interactions depending on the atomic hydrogen concentration. Atomic hydrogen has been shown to etch silicon, to passivate dangling bond defects, and to inactivate both acceptor and donor impurities, although donor impurity inactivation is less stable.

In one embodiment, a tungsten filament is heated to about 1900° C. with electric current, a pressure of an H₂ is about 1 Torr, and a substrate temperature is less than 900° C., and more specifically, the substrate temperature is from about 120° C. to about 200° C. In one embodiment, the substrate temperature is about 150° C. The substrate is heated by halogen lamps. In one embodiment, hydrogen-boron inactivation follows a trap-limited diffusion model. The trap-limited diffusion model is known to one of ordinary skill in the art of semiconductor device manufacturing. About 99% of the dopant in the surface portion of the region of the solar cell is inactivated relatively quickly, and this level of inactivation follows at depths up to several microns with continuing exposure to atomic hydrogen. In an embodiment, unlike traditional selective emitters which interrupt the cell manufacturing process, methods described herein can occur after the cell is fully fabricated. In one embodiment, an original doping for the selective emitter of the solar cell as described herein is provided using diffusion, ion implantation, or other technique known to one of ordinary skill in the art of electronic device manufacturing.

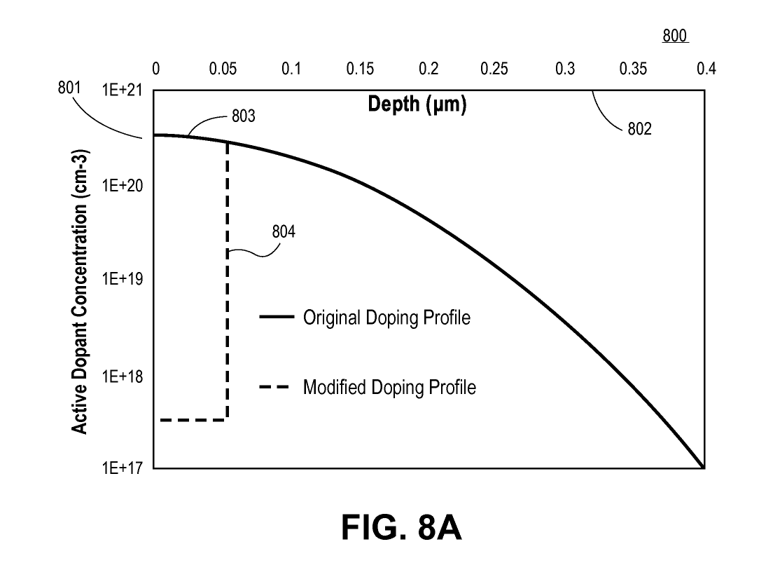

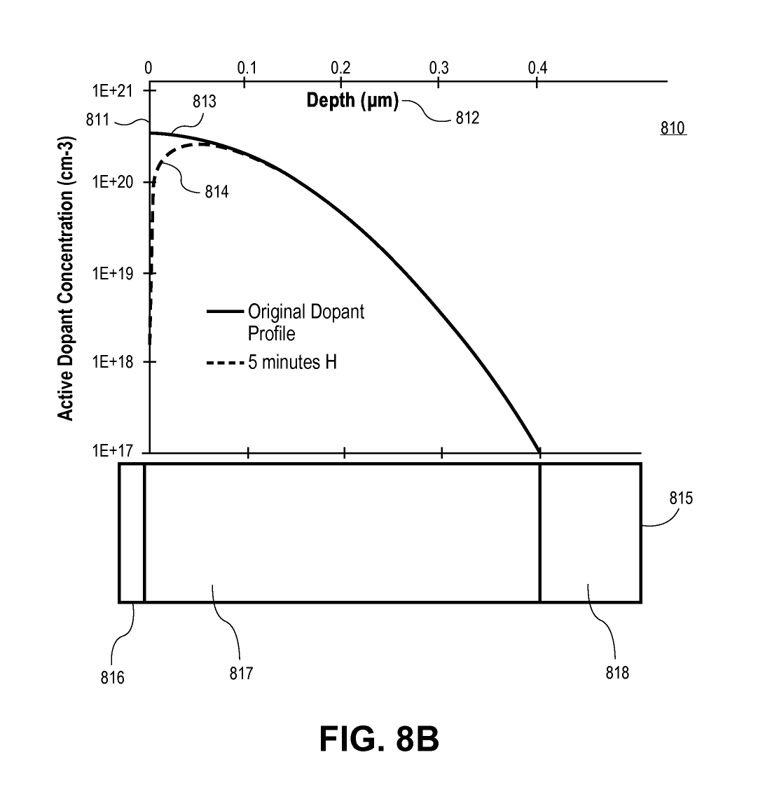

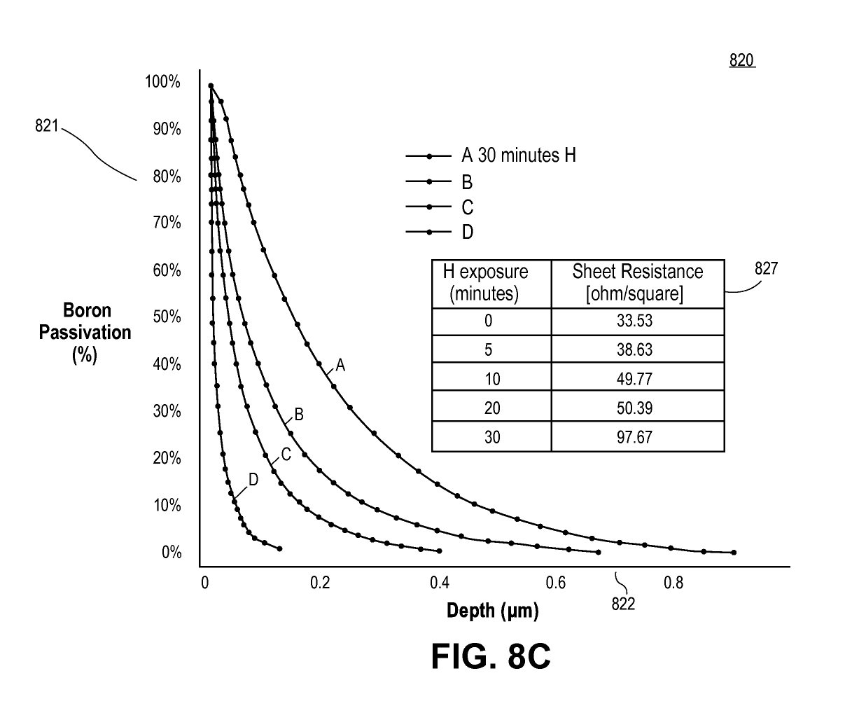

FIG. 8A is a graph 800 illustrating an active dopant concentration 801 against a depth 802 of a p-type doped region of an n-type silicon solar cell according to one embodiment of the invention. Depth 802 indicates a distance from the surface of the doped region. Prior to deactivating, an original active dopant concentration profile 803 has the active dopant concentration that steadily decreases from about 5×10²⁰ cm⁻³ as the depth increases. After deactivating, a modified active dopant concentration profile 804 has the active dopant concentration that increases from about 5×10¹⁷ cm⁻³ at the surface (0 depths) to about 5×10²⁰ cm⁻³ at the depth of about 0.05 μm. In an embodiment, the dopant having the doping profile 803 and doping profile 804 is boron, or other dopant as described herein.

FIG. 8B is a graph 810 illustrating an active dopant concentration 811 against a depth 812 from a surface of a p-type doped region of an n-type silicon solar cell according to one embodiment of the invention. A solar cell 815 has a doped region 817 between a passivation layer 816 and a substrate 818, as described herein. Prior to deactivating, an original active dopant concentration profile 813 has the active dopant concentration that steadily decreases from about 5×10²⁰ cm⁻³ at a surface of the doped region between the passivation layer and the Si solar cell substrate as the depth increases. After exposing the solar cell to hydrogen gas for five minutes, a modified active dopant concentration profile 814 has the active dopant concentration that increases from about 2×10¹⁸ cm⁻³ at the surface of the doped region (0 depths) to about 5×10²⁰ cm⁻³ at the depth of about 0.05 μm in the doped region. In an embodiment, the dopant having the doping profile 813 and doping profile 814 is boron, or other dopant as described herein.

As shown in FIGS. 8A and 8B, the modified doping profile has just enough dopant inactivation or physical lack of active dopants at the surface of the otherwise highly doped region (e.g., selective emitter, back surface field) of the solar cell to decrease surface recombination. Unlike simply starting with a lightly doped emitter as in the conventional technique, this emitter can have low sheet resistance, eliminating power loss and avoiding the requirement of traditional selective emitters to increase number of grid lines. FIGS. 8A and 8B show examples of a doping profile with light doping at the surface to allow for excellent surface passivation followed by higher doping that keeps sheet resistance low. This concept applies for p-type or n-type solar cells.

FIG. 8C is an illustration of a boron-hydrogen (“B—H”) passivation (“inactivation”) 821 as a percentage of the electrically active boron versus a depth 822. A profile A is taken from experimental values of heavily boron-doped silicon. Profiles B, C, and D are simulated (e.g., using a computer) B—H profiles for 20, 10, and 5 minute atomic hydrogen exposures respectively. Typical boron diffusions are less than one micrometer deep. A table 827 shows sheet resistance of the boron doped silicon at a 500 nm depth for different exposure times to hydrogen. As shown in table 827, an unexposed to hydrogen (zero exposure time) boron doped silicon has a starting sheet resistance of about 33 Ω/square. As shown in table 827, for the five minute hydrogenation, the sheet resistance does not substantially change from the starting sheet resistance, and extra gridlines to combat power loss due to the increased resistance are not needed. As shown in FIG. 8C, the boron is about 100% deactivated at the depth from the surface to less than about 0.1 μm. That is, the concentration of the active dopants in the surface portion is more than an order of magnitude lower than that of traditional selective emitters without the penalty of high sheet resistances greater than 100 Ω/square which requires up to 50% more gridlines.

FIG. 6D is an illustration of a cross-sectional view 630 of a selective emitter solar cell according to one embodiment of the invention. As noted above, it is to be understood that an embodiment shown in the FIG. 6D is an illustrative representation and is not necessarily drawn to scale. A solar cell substrate 631 has a front surface 639 and a back surface 640. The solar cell substrate can be one of the solar cell substrates as described above. A selective emitter 632 is adjacent to the front surface of the substrate. The selective emitter can be one of the selective emitters as described above. A conductive grid line 633 is formed adjacent to a portion of the selective emitter 632. The conductive grid line can be one of the solar cell substrates as described above. An AR coating 635 on a passivation layer 636 is deposited on a portion of the selective emitter outside the grid line 633, as described above. In one embodiment, the selective emitter has a p-type dopant, and the substrate has an n-type dopant. In one embodiment, the selective emitter has an n-type dopant, and the substrate has a p-type dopant. As shown in FIG. 6D, an electrical activity of at least a portion of the dopant in a portion of the emitter 632 outside the grid line 633 is deactivated, as described herein. The portion of the emitter 632 outside the grid line 633 has an electrically inactive complex with the dopant 634, as described above. The active dopant concentration at a surface portion of the selective emitter 632 underneath the passivation layer 636 is less than the active dopant concentration at a portion of the selective emitter 632 a distance away from the surface portion and is less than the active dopant concentration in the portion of the emitter 632 below the conductive grid line 633, as described above. In one embodiment, the dopant is distributed substantially uniformly in the selective emitter, as described herein. As shown in FIG. 6C, a back surface field 637 is adjacent to the back surface of the substrate 631, as described herein. In one embodiment, the back surface field has the same type of conductivity as the substrate. In one embodiment, the back surface field has the dopant concentration higher than that of the substrate to form an ohmic like contact with a back contact 638. As shown in FIG. 6C, the back contact 638 is adjacent to the back surface field 637. In one embodiment, a passivation layer (not shown) is deposited between the back surface field and the contact 638 to reduce the surface recombination, as described above.

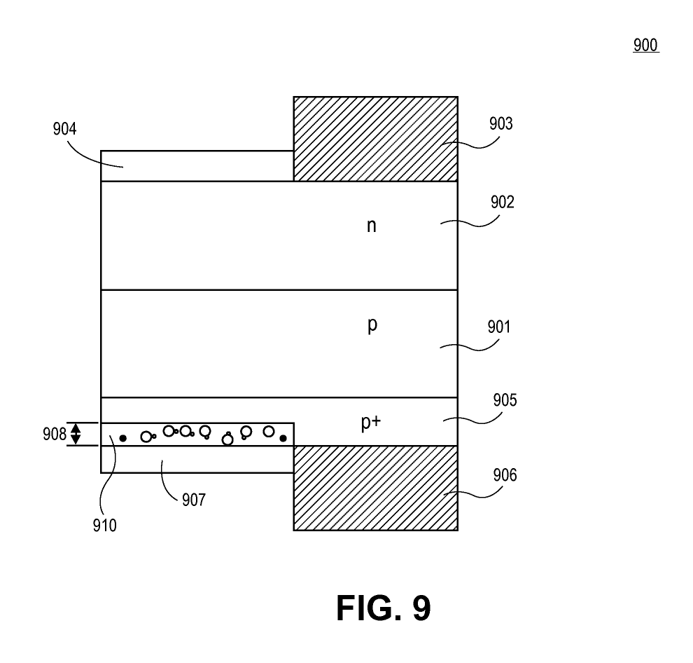

FIG. 9 is an illustration of a cross-sectional view 900 of a selective emitter solar cell according to one embodiment of the invention. A solar cell substrate 901 has a front surface and a back surface, as described above. A selective emitter 902 is adjacent to the front surface of the substrate 901, as described above. In one embodiment, the thickness of the selective emitter is from about 0.001 μm to about 0.5 μm. A conductive grid line 903 is formed adjacent to a portion of the selective emitter 902, as described above. An AR coating on a passivation layer 904 is deposited on a portion of the selective emitter outside the grid line 903, as described above. In one embodiment, the AR coating acts as a passivation layer, as described above.

As shown in FIG. 9, a back surface field 905 is adjacent to the back surface of the substrate 901, as described herein. In one embodiment, the back surface field has the same type of conductivity as the substrate. As shown in FIG. 9, the selective emitter 902 has an n-type dopant, the substrate 901 has a p-type dopant, and the back surface field 905 has a p-type dopant. As shown in FIG. 9, the back surface field 905 has a p-type dopant concentration higher (p+) than a p-type dopant concentration (p) in the substrate 901 to form an ohmic like contact with a back contact 638. In another embodiment, the selective emitter has a p-type dopant, and the back surface field has an n-type dopant concentration higher (n+) than an n-type dopant concentration (n) in the substrate. In one embodiment, the back surface field has the n-type dopant concentration higher than that of the substrate to form an ohmic like contact with a back contact 638.

As shown in FIG. 9, the back grid line contact 906 is adjacent to the back surface field 905. A passivation layer 907 is deposited onto the back surface field 905 to reduce the surface recombination, as described above. In one embodiment, an AR coating is deposited onto the passivation layer, as described above. In one embodiment, an AR coating acts as a passivation layer, as described above.

As shown in FIG. 9, an electrical activity of at least a portion of the dopant in a portion 910 of the back surface field 905 adjacent to the passivation layer 907 and outside the grid line 906 is deactivated, as described herein. As shown in FIG. 9, the portion 910 of the back surface field 905 outside the grid line 906 has an electrically inactive complex with the dopant, as described above. The active dopant concentration at a surface portion of the back surface field 905 adjacent to the passivation layer 907 is less than the active dopant concentration at a portion of the back surface field 905 at a distance 908 away from the surface portion and is less than the active dopant concentration in the portion of the back surface field 905 below the conductive grid line 906, as described above. In one embodiment, the dopant is distributed substantially uniformly in the back surface field 905, as described herein.

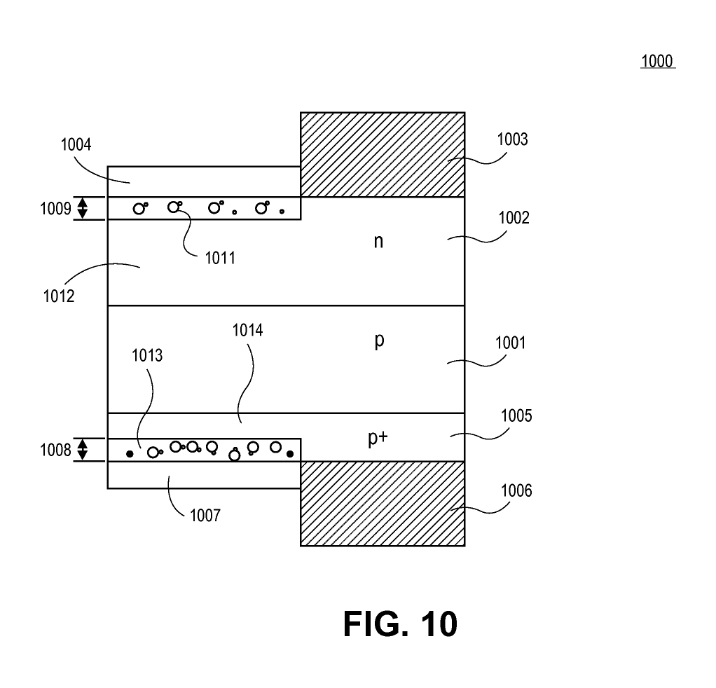

FIG. 10 is an illustration of a cross-sectional view 1000 of a bifacial selective emitter solar cell having a grid line metallization on the back and a reduced rear-surface recombination velocity according to one embodiment of the invention. A solar cell substrate 1001 has a front surface and a back surface, as described above. A selective emitter 1002 is adjacent to the front surface of the substrate 1001, as described above. A conductive grid line 1003 is formed adjacent to a portion of the selective emitter 1002, as described above. An AR coating on a passivation layer 1004 is deposited on the portion of the selective emitter outside the grid line 1003, as described above. In one embodiment, the AR coating acts as a passivation layer, as described above.

As shown in FIG. 10, a back surface field 1005 is adjacent to the back surface of the substrate 1001, as described herein. In one embodiment, the back surface field has the same type of conductivity as the substrate. As shown in FIG. 10, the selective emitter 1002 has an n-type dopant, the substrate 1001 has a p-type dopant, and the back surface field 1005 has a p-type dopant. As shown in FIG. 10, the back surface field 1005 has a p-type dopant concentration higher (p+) than a p-type dopant concentration (p) in the substrate 1001 to form an ohmic like contact with a back grid line 1006. In another embodiment, the selective emitter has a p-type dopant, and the back surface field has an n-type dopant concentration higher (n+) than an n-type dopant concentration (n) in the substrate form an ohmic like contact with a back grid line contact 1006. In one embodiment, the thickness of the selective emitter is from about 0.001 μm to about 0.5 μm. In one embodiment, the thickness of the back surface field is from about 0.001 μm to about 0.5 μm.

As shown in FIG. 10, back grid line contact 1006 is adjacent to the back surface field 1005. A passivation layer 1007 is deposited onto the back surface field 1005 to reduce the surface recombination, as described above. In one embodiment, an AR coating is deposited onto the passivation layer, as described above. In one embodiment, an AR coating acts as a passivation layer, as described above.

As shown in FIG. 10, an electrical activity of at least a portion of the dopant in a portion 1011 of the selective emitter 1002 adjacent to the passivation layer 1004 and outside the grid line 1003 and an electrical activity of at least a portion of the dopant in a portion 1013 of the back surface field 1005 adjacent to the passivation layer 907 and outside the grid line 906 are deactivated, as described herein. As shown in FIG. 10, a portion 1011 of the selective emitter 1002 outside the grid line 1003 has an electrically inactive complex with the n-type dopant and a portion 1013 of the back surface field 1005 outside the grid line 1006 has an electrically inactive complex with the p-type dopant, as described above. The surface portion 1011 adjacent to the passivation layer 1004 has the active dopant concentration that is less than the active dopant concentration in the portion 1012 at a distance 1009 away from the surface portion and is less than the active dopant concentration in the portion of the selective emitter 1002 below the conductive grid line 1003. The surface portion 1013 of the back surface field 1005 adjacent to the passivation layer 1007 is less than the active dopant concentration in a portion 1014 of the back surface field 1005 at a distance 1008 away from the surface portion and is less than the active dopant concentration in the portion of the back surface field 1005 below the conductive grid line 1006, as described above. In one embodiment, the n-type dopant is distributed substantially uniformly in the selective emitter, and the p-type dopant is distributed substantially uniformly in the back surface field, as described herein.

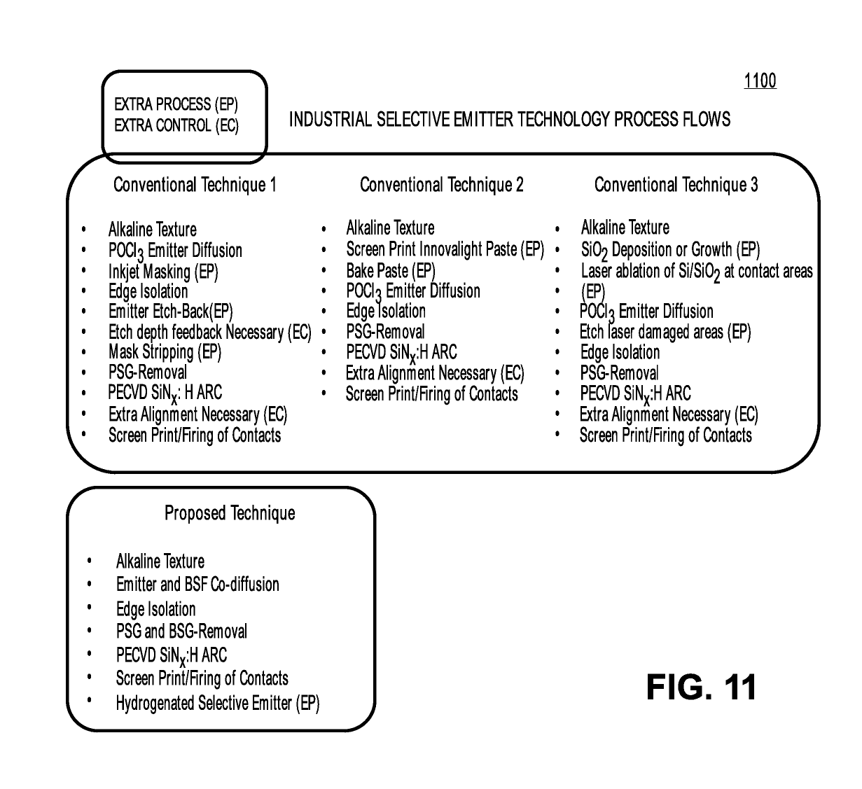

FIG. 11 is a table view 1000 to compare conventional techniques to fabricate a solar cell having a selective emitter with a method to fabricate a solar cell according to one embodiment of the present invention. FIG. 11 shows extra processing steps (“EP”) and extra control steps (“EC”) required by three conventional techniques relative to one embodiment of a proposed technique to fabricate a solar cell using deactivation as described herein. In one embodiment, the proposed technique to fabricate a solar cell using deactivation is a one-step process which occurs after a solar cell is fully fabricated. The conventional selective emitter technologies interrupt the cell process flow.

FIG. 12A is an illustration of a cross-sectional view of a portion of a solar cell according to one embodiment of the invention. A portion of a solar cell 1200 can be one of the solar cells as depicted in FIGS. 2, 3, 4, and 5. A region 1202 is formed on a substrate, as described above. Region 1202 has a dopant. The dopant is represented by a plurality of electrically active dopant particles, such as an active dopant particle 1203, as described above. In an embodiment, the region 1202 is heavily doped to have concentration of active dopants more than about 2×10²⁰ cm⁻³. In one embodiment, the region 1202 is a selective emitter of the solar cell. In one embodiment, the thickness of the region 1202 is from about 0.001 μm to about 0.5 μm. In one embodiment, the region 1202 is a back surface field of the solar cell. In one embodiment, the doped region has a p-type conductivity. In one embodiment, the doped region has an n-type conductivity. In one embodiment, the dopant is at least one of boron (B), aluminum (Al), gallium (Ga), indium (In), thallium (Tl), and other acceptor dopant. In one embodiment, the dopant is at least one of nitrogen (N), phosphorus (P), arsenic (As), antimony (Sb), bismuth (Bi) and other donor dopant. As shown in FIG. 12A, the active dopant particles are distributed substantially uniformly in region 1202.

As shown in FIG. 12A, a semiconductor layer 1205 is formed on a portion 1209. In an embodiment, the semiconductor layer 1205 is an intrinsic semiconductor layer having active dopant concentration less than about 10¹⁵ cm⁻³. In an embodiment, the semiconductor layer 1205 is a lightly doped semiconductor layer having active dopant concentration less than about 10¹⁸ cm⁻³. As shown in FIG. 12A, a concentration of electrically active dopant particles, such as an electrically active particle 1213 in semiconductor layer 1205 is less than the concentration of the electrically active dopant particles in the doped layer 1202. In an embodiment, the electrically active dopant concentration in the semiconductor layer 1205 is one more orders of magnitude lower than the electrically active dopant concentration in the doped layer 1202.

In an embodiment, the semiconductor layer 1205 is an intrinsic silicon, or any other intrinsic semiconductor layer. In an embodiment, the semiconductor layer 1205 is a lightly doped silicon, or any other lightly doped semiconductor layer. In an embodiment, the active dopant concentration in the semiconductor layer 1205 is less than about 5×10¹⁷ cm⁻³, and the active dopant concentration in the doped region 1202 is at least about 2×10²⁰ cm⁻³. In one embodiment, the thickness of the semiconductor layer 1205 is less than about 100 nm. In one embodiment, the thickness of the semiconductor layer 1205 is from about 1 nm to about 50 nm.

As shown in FIG. 12A, a passivation layer 1206 is deposited onto the semiconductor layer 1205. In one embodiment, the thickness of the passivation layer is from about 10 nm to about 200 nm. In an embodiment, the thickness of the passivation layer is from about 70 nm to about 100 nm.

In an embodiment, the passivation layer 1206 is silicon nitride. In an embodiment, the passivation layer 1206 is silicon oxide. In an embodiment, the passivation layer 1206 is aluminum oxide. In an embodiment, an antireflective (“AR”) coating (not shown) is formed on the passivation layer 1206, as described above. In an embodiment, the passivation layer 1206 acts as an AR coating, as described above. In an embodiment, the semiconductor layer 1205 is deposited by an epitaxial growth process using for example, a PECVD technique, or other deposition technique known to one of ordinary skill in the art of electronic device manufacturing.

In an embodiment, prior to at least one of the passivation layer and AR coating is deposited, a thin, intrinsic epitaxial layer is grown on the surface of a portion of the doped region of the solar cell using for example the same PECVD tool used for the antireflection coating. In an embodiment, the intrinsic silicon layer is deposited onto the doped region of the silicon substrate not covered by the grid line. In an embodiment, the lightly doped silicon layer is deposited onto the doped region of the silicon substrate not covered by the grid line.

FIG. 12B is a view similar to FIG. 12A after a grid line is deposited onto the region 1202 of the solar cell according to one embodiment of the invention. As shown in FIG. 12B, the region 1202 has a portion 1208 and a portion 1209. A conductive grid line 1204 is deposited on the portion 1208 of region 1202. Semiconductor layer 1205 is formed on portion 1209 not covered by the grid line 1204, as shown in FIG. 12B. Passivation layer is deposited on semiconductor layer 1206, as described above. In one embodiment, the grid line 1204 is deposited onto the portion 1208 of the region 1202 through passivation layer 1206 and semiconductor layer 1205, as described herein.

In an embodiment, depositing a grid line onto the doped region 1202 includes screen printing a metal paste containing an etchant onto the AR layer, passivation layer, e.g., passivation layer 1206, or both. The etchant in the metal paste etches through the AR layer, passivation layer or both and through the semiconductor layer 1205 down to the doped region 1202 so that the metal paste is placed in direct contact with the doped region 1202. In an embodiment, the metal paste containing an etchant is silver, aluminum, or any other metal paste known to one of ordinary skill in the art of electronic device manufacturing. In one embodiment, the silver paste screen printed onto the doped region of the silicon solar cell substrate is heated to about 700° C. to etch through the AR layer, passivation layer, or both and through the semiconductor layer, e.g., semiconductor layer 1205, down to the doped silicon region.

In an embodiment, the concentration of active dopant particles, such as an active dopant particle 1213 in a surface portion 1211 that comprises semiconductor layer 1205 is smaller than a concentration of active dopant particles in the portion 1209 of the region 1202. In an embodiment, the concentration of electrical active dopants in the surface semiconductor layer portion 1211 not covered by grid line 1205 is smaller than the concentration of electrically active dopants in a portion 1208 of the region 1202 underneath the grid line 1204. In one embodiment, the electrically active dopant concentration in region 1208 beneath the grid line is more than one order of magnitude greater than the electrically active dopant concentration in the semiconductor layer 1205 on the region 1209 of the doped region 1202 outside the grid line 1204.

In one embodiment, a doping profile is generated along the depth of the semiconductor layer 1205 and region 1202 in a direction 1212 that has substantially low active dopant concentration (e.g., no greater than 5×10¹⁷ cm⁻³) along the thickness of the semiconductor layer 1205, and substantially high active dopant concentration (at least 5×10²⁰ cm⁻³) in at least the surface portion 1207 of the region 1202.

In an embodiment, the doping profile generated along the depth of the semiconductor layer 1205 and region 1202 in a direction 1212 is a step-like dopant profile similar to the doping profile 804 depicted in FIG. 8A. In one embodiment, the doping profile in a depth direction 1212 has substantially low and constant active dopant concentration (e.g., no greater than 5×10¹⁷ cm⁻³) along the depth of the semiconductor layer 1205, and substantially high active dopant concentration (at least 5×10²⁰ cm⁻³) in the surface portion 1207 along the depth of the region 1202. In an embodiment, the dopant profile is generated along the depth of the semiconductor layer 1205 and region 1202 in a direction 1212 that is similar to the doping profile 814 depicted in FIG. 8B.

Selective emitter cell architectures are one avenue for increasing industrial solar cell efficiency. N-type cell based technology is also gaining considerable attention for the same purpose. In an embodiment, a novel, single step selective emitter process using atomic hydrogen to passivate boron acceptor impurities is described. Grid lines act as a mask to hydrogenation, which lowers the surface concentration of electrically active boron between grid lines. Using EDNA to model this complex emitter, it was shown that Jsc can be increased in the emitter by 0.94 mA/cm² with a short, low temperature atomic hydrogen treatment. A hydrogenation system has been developed, and initial experimental results on aluminum doped polycrystalline thin films shows its effectiveness. Cell fabrication is being developed to test this process on real solar cells to verify theoretical results. Special processing considerations will be discussed.

Selective emitter cell architectures are an interesting proposition for the solar industry. Many processing schemes have been proposed laser-based doping, emitter etch back techniques, and ion implantation to name a few. Most work, naturally, has focused on selective n-type emitters for p-type cells. However, there is growing interest in moving to n-type cells despite abandoning the elegance of the aluminum paste BSF/front side metallization fire through in order to reach efficiencies above 20%. Besides Sanyo and Sunpower, with unconventional, high-efficiency architectures, Yingli's Panda cells are some of the only commercially available n-type cells, which currently do not employ a selective emitter.

In an embodiment, a novel, one step selective emitter using atomic hydrogen to passivate boron acceptor impurities is described. The idea is simple: a screen printed grid makes ohmic like contact to a highly boron-doped p+ emitter. Gridlines act as a mask during an atomic hydrogenation step which lowers the sheet resistance between the gridlines by passivating boron. A hydrogenation system has been developed, and initial experimental results on aluminum doped polycrystalline thin films shows its effectiveness. Cell fabrication is being developed to test this process on real solar cells to verify experimental results. Special processing considerations will be discussed.

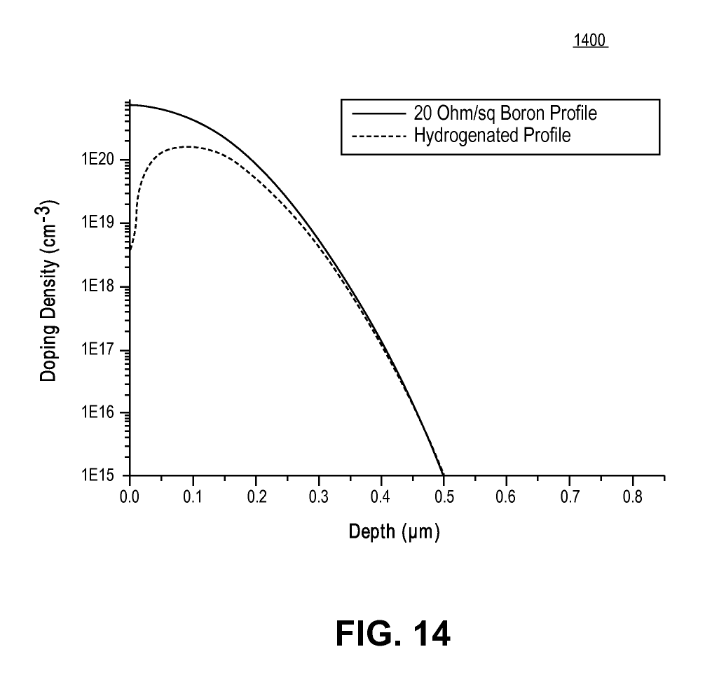

EDNA, a new emitter modeling software, was used to model the effect of hydrogen passivation of boron dopants. The functionality of user-defined dopant profiles made this work possible. The treatment of surface recombination velocity was not built into the program and was a user-defined parameter not linked to the dopant profile. However, it has been reported in the literature that for passivated surfaces, both n-type and p-type diffusions show surface recombination velocities (SRV) increasing with dopant concentration. For the presented work, it was assumed that SRV was influenced solely by boron peak dopant density. This assumption has been shown experimentally for both boron and phosphorus emitters. For a theoretical comparison, a boron dopant profile was modified from the one generated by EDNA to include the hydrogen passivated profile calculated for real B—H complex data on highly doped material. These profiles were then entered into the “Measured Data” section of the program to determine the effects on the quality of the emitter. Hydrogen passivation of boron has been characterized by Herrero, et al., and the concentration of B—H complexes was found to reach 99% passivation near the surface after only 30 minutes of hydrogenation at T_{substrate}=150° C. The B—H complex data were digitized using OriginPro 8.6. FIG. 14 shows the original boron profile as well as the hydrogenated profile based on the experimental data.

EDNA was used to compare the emitter characteristics of the two doping profiles in FIG. 14. It should be noted that the program does not consider current generated or collected from the base. All simulated emitters were illuminated with AM1.5 global data built into the software.

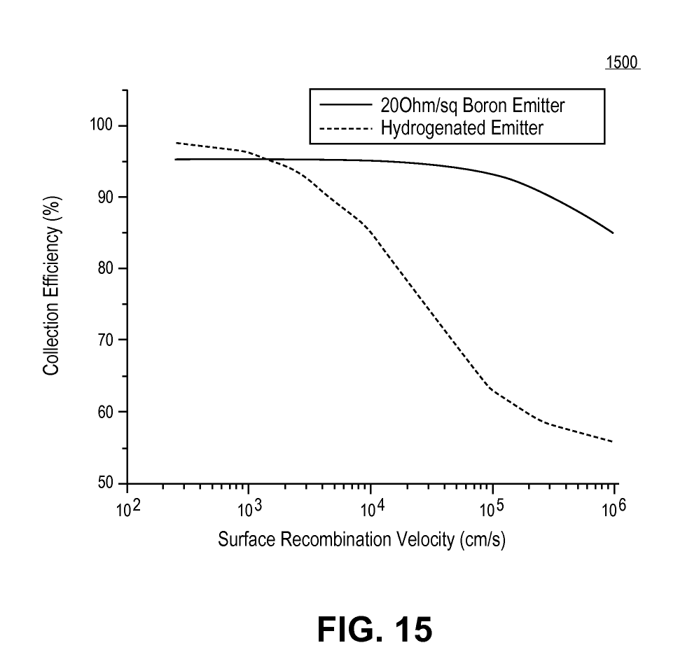

It is possible that a hydrogenated emitter will not behave the same way as a lightly doped emitter in terms of decreased SRV. It is also possible that high quality passivation could prove difficult at temperatures below 200° C. Therefore, the surface recombination velocity of both profiles was varied from 250 cm/s to 1×10⁶ cm/s. The behavior of each emitter is shown in FIG. 15. At low SRV, the hydrogenated emitter out-performs the heavily doped emitter. Absolute increase in J_{sc} from the hydrogenated emitter is as much as 0.94 mA/cm². This value is typical for both experimental and theoretical studies of selective emitters. However, as SRV increases, the hydrogenated emitter experiences severe losses due to surface SRH recombination according to the model. The original boron profile is less sensitive to surface recombination.

A hydrogenation system with independent substrate heating was constructed. Hydrogen gas is catalytically cracked by a heated tungsten filament. The advantage of this system is an absence of plasma damage. The tungsten filament in our system is 10 cm away from the substrate, minimizing heating from the filament. The substrate is heated by two 500 W halogen lamps directly above the substrate holder. Initial acceptor impurity passivation studies have been carried out by varying substrate temperature and gas pressure. Polycrystalline films of thickness 300 nm were prepared on glass by top-down aluminum induced crystallization. Films were used to measure increase in film resistivity due to hydrogenation treatments. Samples were then thermally recovered to the original resistivity values.

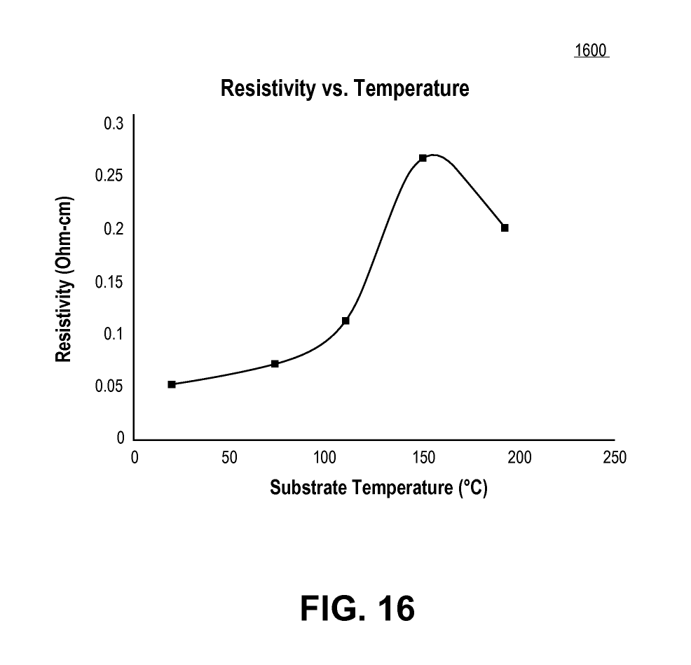

FIG. 16 shows results for varying substrate temperature on increase in resistivity for samples hydrogenated for 30 minutes at 1 Torr with a filament temperature of T_{fil}=1900° C. Original resistivity was just over 0.05 Ω-cm. Not surprisingly, the optimal substrate temperature from this study was 150° C. These samples showed an average increase in resistivity of over 400%. At T_{sub}=190° C., resistivity is less because of the cooling time at the end of the process, where, for a period of several minutes, the sample was above the temperature at which B—H complexes begin to break.

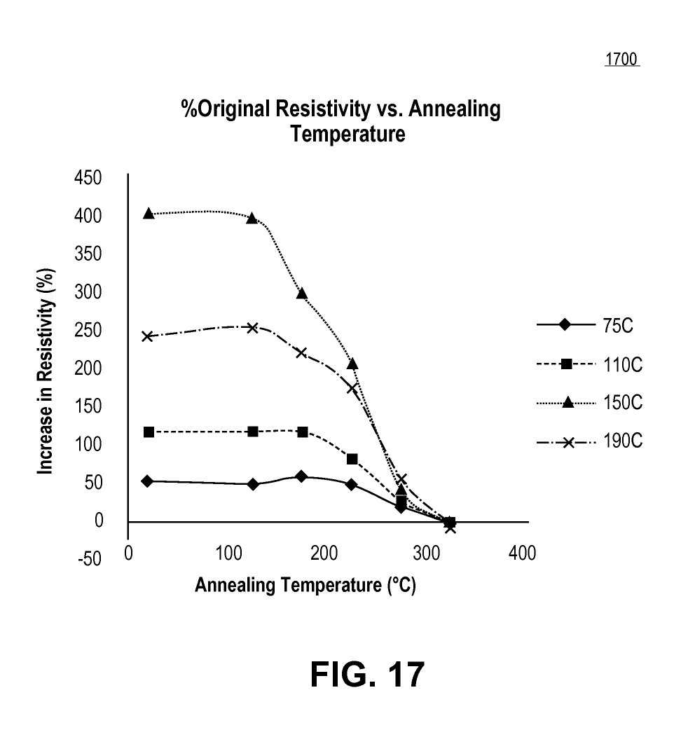

Thermal recovery of the resistivity of these samples versus temperature is shown in FIG. 17. Samples were sequentially annealed for 30 minutes from 125° C. to 325° C. in steps of 50° C. with resistivity measured after each heating cycle until the original resistivity was recovered. This figure indicates that B—H complexes are stable for more than an hour at temperatures above 175° C.

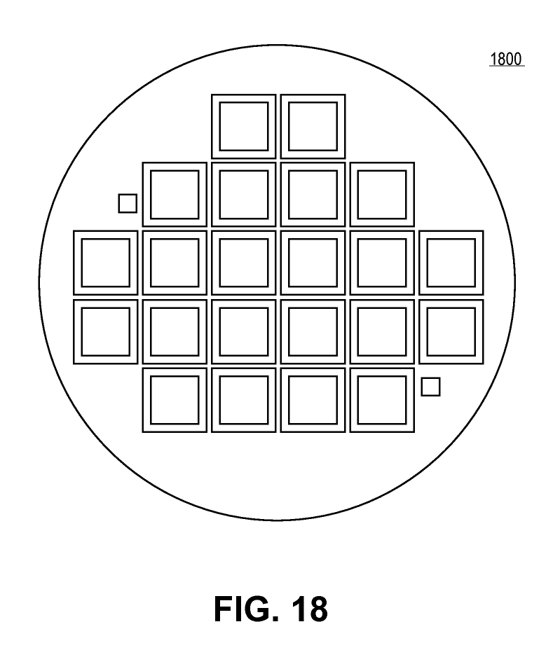

Solar cells (e.g., as shown in FIG. 18) have been fabricated both by traditional diffusion as well as Top-down aluminum induced crystallization (TAIC). Results on hydrogenation will be presented. Several considerations must be made for cell processing based on simulation results and hydrogenation studies. First, it is clear that a passivation layer must be applied to determine whether atomic hydrogen treatment can be used as a selective emitter technology. This is true of normal selective emitter structures because, as shown in FIG. 15, lightly doped emitters are more susceptible to SRH surface recombination. Second, any passivation layer must be deposited at temperatures below about 200° C. or quickly to retain the desired profile. This is assuming heating and deposition times of less than an hour, which is dependent on deposition configuration and processing parameters. For example, the PlasmaTherm PECVD system we use for anti-reflection coatings requires only 5 minutes to reach substrate temperatures of 250° C. Heavily boron doped emitters will be created on n-type wafers. Various hydrogenation times will be performed after metallization and prior to surface passivation.

A theoretical study has been carried out based on experimental data for hydrogenation of heavily doped emitters. The simulations indicate that a hydrogenated emitter is capable of increases in J_{sc} comparable to those reported in the literature for traditional selective emitter schemes. However, these improvements are dependent on the ability of hydrogenated emitters to behave as though they were lightly doped near the surface. The main contribution to the increased collection efficiency stems from the ability of lightly doped surfaces to achieve lower surface recombination values upon passivation. Whether hydrogen passivated boron impurities exhibit the same behavior must be determined experimentally. This requires high-quality surface passivation at temperatures below about 200° C. in order to retain the passivation during this final cell processing step. Further steps, such as tabbing and lamination must also be kept to a low thermal budget in order for the hydrogenated selective emitter to be a viable technique.

In the foregoing specification, embodiments of the invention have been described with reference to specific exemplary embodiments thereof. It will be evident that various modifications may be made thereto without departing from the broader spirit and scope of the embodiments of the invention. The specification and drawings are, accordingly, to be regarded in an illustrative sense rather than a restrictive sense.

1-83. (canceled)

84. A solar cell comprising:
a first region formed on a first side of a substrate, the first region having a first dopant; and
a first grid line over a first portion of the first region, wherein an electrical activity of a part of the first dopant is deactivated in a second portion of the first region outside the grid line.

85. The solar cell of claim 84, wherein the first dopant is distributed substantially uniformly in the second portion.

86. The solar cell of claim 84, wherein the portion of the first dopant is bound to chemical species and is electrically inactive.

87. The solar cell of claim 84, wherein the region is a selective emitter formed on a solar cell substrate.

88. The solar cell of claim 84, wherein the region is a back surface field of the solar cell.

89. The solar cell of claim 84, wherein an electrically active first dopant concentration at a surface portion of the first portion is smaller than the electrically active first dopant concentration at a distance away from the surface portion.

90. The solar cell of claim 84, further comprising
a passivation layer on the first region, wherein the grid line is in direct contact with the first portion of the first region.

91. The solar cell of claim 84, further comprising
a second region having a second dopant on a second side of the substrate; and
a second grid line adjacent to the second region.

92. A solar cell, comprising:
a conductive grid line on a first portion of a first region on a first side of a substrate, wherein a concentration of active dopants at a first surface portion on a second portion of the first region outside the grid line is less than the concentration of active dopants at a distance away from the first surface portion.

93. The solar cell of claim 92, wherein the dopant is distributed substantially uniformly in the second portion.

94. The solar cell of claim 92, wherein a portion of the dopant is deactivated in the second portion of the first region.

95. The solar cell of claim 92, further comprising
a passivation layer over the first region.

96. The solar cell of claim 92, further comprising
a second region formed on a second side of the substrate; and
a second grid line adjacent to the second region, wherein a dopant in a portion of the second region is deactivated.

97. The solar cell of claim 92, wherein the first surface portion comprises an intrinsic semiconductor layer.

98. The solar cell of claim 92, wherein the first surface portion comprises a lightly doped semiconductor layer having active dopant concentration less than about 10¹⁹ cm⁻³, and the second portion comprises heavily doped semiconductor layer having active dopant concentration more than 10¹⁹ cm⁻³.

99. A method to manufacture a solar cell comprising:
deactivating an electrical activity of a dopant in a first portion of a region of the solar cell by exposure to chemical species using a grid line deposited on a second portion of the region as a mask.

100. The method of claim 99, further comprising
generating a dopant profile having a concentration of active dopants at a surface portion of the first portion of the region smaller than the concentration of active dopants at a distance away from the surface portion.

101. The method of claim 99, further comprising
depositing a passivation layer on the region, wherein the chemical species deactivates the dopant through the passivation layer.

102. The method of claim 99, wherein the deactivating comprises
reacting the dopant with an atomic element of the chemical species; and
forming an electrically inactive complex based on the reacting.

103. The method of claim 99, further comprising depositing an antireflective coating over the region, wherein the chemical species deactivates the dopant through the antireflective coating.

104. The method of claim 99, wherein the chemical species includes atomic hydrogen, deuterium, copper, lithium, or a combination thereof, and wherein deactivating comprises exposing the first portion of the region outside the grid line to the atomic hydrogen, deuterium, copper, lithium, or a combination thereof.

105. The method of claim 99, further comprising
supplying the chemical species to the first portion of the region of the solar cell placed in a chamber;
generating atomic elements from the chemical species; and
exposing the dopant in the first portion of the region to the atomic elements.

106. A method to manufacture a solar cell comprising:
generating a dopant profile having a concentration of active dopants at a first surface portion on a first portion of a region of solar cell smaller than the concentration of active dopants at a distance away from the surface portion, wherein a grid line is on a second portion of the region of the solar cell.

107. The method of claim 106, wherein the first portion has the first surface portion, and wherein the dopant profile is generated by
deactivating an electrical activity of a dopant at the first surface portion of the first portion of the region of the solar cell by exposure to chemical species.

108. The method of claim 106, wherein the dopant profile is generated by depositing a semiconductor layer onto the first portion of the region of the solar cell, the semiconductor layer having the first surface portion, wherein the concentration of active dopants at the first surface portion is less than the concentration of active dopants in the first portion.

109. The method of claim 106, further comprising
etching through any layers above the semiconductor layer until a contact resistance of less than 1 ohm×cm² is achieved.
